(19) United States
(12) Patent Application Publication
(10) Pub. No.: US 2021/0240632 A1
(43) Pub. Date: Aug. 5, 2021

(54) MEMORY CONTROLLER AND OPERATING METHOD THEREOF

(71) Applicant: SK hynix Inc., Gyeonggi-do (KR)

(72) Inventor: Young Ho JEON, Gyeonggi-do (KR)

(21) Appl. No.: 16/930,863

(22) Filed: Jul. 16, 2020

(30) Foreign Application Priority Data
Feb. 5, 2020 (KR) 10-2020-0013885

(51) Int. Cl. G06F 12/10

(52) U.S. Cl. CPC G06F 12/10; G06F 2212/657

(57) ABSTRACT

The present disclosure relates to an electronic device. A memory controller stores a stream ID by changing the stream ID on the basis of the number of updates of data and the number of times garbage collection is performed. The memory controller controlling a memory device includes a flash transition layer generating a mapping relationship of first data received from a host on the basis of a first stream ID included in the first data, a stream ID controller receiving second data for updating the first data stored in the memory device on the basis of the mapping relationship generated based on the first stream ID, and determining a second stream ID to be assigned to the second data, and a request controller outputting a program command for storing the first data and third data including the second data and the second stream ID in the memory device.

### CROSS-REFERENCE TO RELATED APPLICATION

The present application claims priority under 35 U.S.C. § 119(a) to Korean patent application number 10-2020-0013885, filed on Feb. 5, 2020, in the Korean Intellectual Property Office, the entire disclosure of which is incorporated by reference herein.

### BACKGROUND

### 1. Technical Field

Various embodiments relate generally to an electronic device, and more particularly, to a memory controller and an operating method thereof.

### 2. Related Art

A storage device may store data in response to control of a host device such as a computer, a smartphone, or a smartpad. Examples of storage devices include a device for storing data in a magnetic disk, such as a hard disk drive (HDD), and a device for storing data in a semiconductor memory, such as a solid state drive (SSD) or a memory card, especially in a nonvolatile memory.

A storage device may include a memory device storing data and a memory controller controlling the memory device. A memory device may be a volatile memory or a nonvolatile memory. Examples of nonvolatile memories include read only memory (ROM), programmable ROM (PROM), electrically programmable ROM (EPROM), electrically erasable and programmable ROM (EEPROM), flash memory, phase-change RAM (PRAM), magnetic RAM (MRAM), resistive RAM (RRAM), and ferroelectric RAM (FRAM).

### SUMMARY

Various embodiments of the present disclosure are directed to a memory controller changing and storing a stream ID on the basis of the number of updates of data and the number of times garbage collection is performed, and a method of operating the memory controller.

According to an embodiment, a memory controller controlling a memory device may include a flash transition layer generating a mapping relationship of first data received from a host on the basis of a first stream ID included in the first data, a stream ID controller receiving second data for updating the first data stored in the memory device on the basis of the mapping relationship generated based on the first stream ID, and determining a second stream ID to be assigned to the second data, and a request controller outputting a program command for storing the first data in the memory device and a program command for storing third data including the second data and the second stream ID in the memory device, wherein the request controller determines the program command for storing the third data in the memory device on the basis of the mapping relationship generated by the flash transition layer on the basis of the second stream ID.

According to an embodiment, a method of operating a memory controller controlling a memory device may include receiving first data from a host, generating a mapping relationship of the first data on the basis of a first stream ID included in the first data, outputting a program command for storing the first data in the memory device on the basis of the mapping relationship, receiving second data for updating the first data from the host, and determining a second stream ID to be assigned to the second data.

According to an embodiment, a memory system may include a memory device suitable for storing current data together with a current stream identification (ID) into a storage region corresponding to the current stream ID, and a controller suitable for counting a number of times that a logical address is provided for updating the current data with updated data to generate a first number, counting a number of times that a garbage collection operation is performed on a storage area corresponding to the logical address to generate a second number, adjusting, in response to a request of updating the current data, a value of the current steam ID resulting in an adjusted stream ID based on the first and second numbers, controlling the memory device to store the updated data together with the adjusted stream ID in a storage region corresponding to the adjusted stream ID and invalidating the current data together with the current stream ID.

### BRIEF DESCRIPTION OF THE DRAWINGS

FIG. 1 is a block diagram illustrating a storage device;

FIG. 2 is a diagram illustrating a stream ID assigned to host data;

FIG. 3 is a diagram illustrating host data to which a stream ID is assigned;

FIG. 4 is a diagram illustrating the configuration of a memory controller receiving a request, an address and data from a host, and storing the received data in a memory device;

FIG. 5 illustrates data stored in a memory device based on an initial stream ID;

FIG. 6 is a diagram illustrating operations of a memory controller after update data is received from a host;

FIG. 7 illustrates operations of a stream ID controller outputting new program data after receiving update data from a host;

FIG. 8 is a diagram illustrating maintaining or changing host data;

FIG. 9 illustrates data stored in a memory device based on a changed stream ID;

FIG. 10 illustrates data stored in a memory device after an existing mapping relationship is invalidated;

FIG. 11 is a diagram illustrating a stream ID which is changed when the stream ID is 1 or 10;

FIG. 12 is a diagram illustrating the structure of a memory device, such as that shown in FIG. 1;

FIG. 13 is a diagram illustrating a memory block;

FIG. 14 is a diagram illustrating operations of a memory controller according to an embodiment of the present disclosure;

FIG. 15 is a diagram illustrating operations of a memory controller according to an embodiment of the present disclosure;

FIG. 16 is a diagram illustrating operations of a memory controller according to an embodiment of the present disclosure;

FIG. 17 is a diagram illustrating another embodiment of a memory controller FIG. 1;

FIG. 18 is a block diagram illustrating a memory card system to which a storage device is applied according to an embodiment;

FIG. 19 is a block diagram illustrating an example of a solid state drive (SSD) system to which a storage device is applied according to an embodiment of the present disclosure; and

FIG. 20 is a block diagram illustrating a user system to which a storage device is applied according to an embodiment.

### DETAILED DESCRIPTION

Specific structural and functional description is provided only to describe embodiments of the invention. However, the invention may be configured or carried out in various other ways. Thus, the present invention is not limited to the disclosed embodiments. Also, throughout the specification, reference to “an embodiment,” “another embodiment” or the like is not necessarily to only one embodiment, and different references to any such phrase are not necessarily to the same embodiment(s).

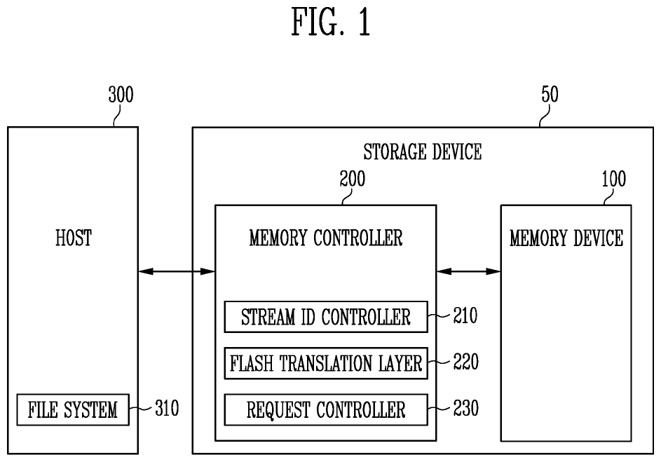

FIG. 1 is a block diagram illustrating a storage device 50.

Referring to FIG. 1, the storage device 50 may include a memory device 100 and a memory controller 200.

The storage device 50 may be configured to store data in response to control of a host 300. Examples of the storage device 50 include a cellular phone, a smartphone, an MP3 player, a laptop computer, a desktop computer, a game player, a TV, a tablet PC, or an in-vehicle infotainment system.

The storage device 50 may be configured as any of various types of storage devices according to a host interface corresponding to a communication method with the host 300. For example, the storage device 50 may be configured as a solid state drive (SSD), a multimedia card in the form of an MMC, an eMMC, an RS-MMC and a micro-MMC, a secure digital card in the form of an SD, a mini-SD and a micro-SD, a universal serial bus (USB) storage device, a universal flash storage (UFS) device, a Personal Computer Memory Card International Association (PCMCIA) card type storage device, a peripheral component interconnection (PCI) card type storage device, a PCI express (PCI-E) card type storage device, a compact flash (CF) card, a smart media card, and/or a memory stick.

The storage device 50 may be manufactured as any of various types of packages. For example, the storage device 50 may be manufactured as a package-on-package (POP), a system-in-package (SIP), a system-on-chip (SOC), a multi-chip package (MCP), a chip-on-board (COB), a wafer-level fabricated package (WFP), and/or a wafer-level stack package (WSP).

The memory device 100 may store data. The memory device 100 may operate in response to control of the memory controller 200. The memory device 100 may include a memory cell array including a plurality of memory cells storing data. The memory cell array may include a plurality of memory blocks. Each of the memory blocks may include a plurality of memory cells. The plurality of memory cells may form a plurality of pages. According to an embodiment, a page may be a unit for storing data in the memory device 100, or reading data stored in the memory device 100. The memory block may be a unit for erasing data.

According to an embodiment, examples of the memory device 100 include a Double Data Rate Synchronous Dynamic Random Access Memory (DDR SDRAM), a Low Power Double Data Rate4 (LPDDR4) SDRAM, a Graphics Double Data Rate (GDDR) SDRAM, a Low Power DDR (LPDDR) SDRAM, a Rambus Dynamic Random Access Memory (RDRAM), a NAND flash memory, a vertical NAND flash memory, a NOR flash memory device, a resistive random access memory (RRAM), a phase-change memory (PRAM), a magnetoresistive random access memory (MRAM), a ferroelectric random access memory (FRAM), and a spin transfer torque random access memory (STT-RAM). By way of example, features and aspects of the present invention are described below in the context in which the memory device 100 is a NAND flash memory.

The memory device 100 may have a two-dimensional array structure or a three-dimensional array structure. Hereinafter, the three-dimensional array structure is described as an embodiment. However, the present disclosure is not limited thereto. The present disclosure may also be applied not only to a flash memory in which a charge storage layer includes a conductive floating gate (FG), but also to a charge trap flash (CTF) memory in which a charge storage layer includes an insulating layer.

According to an embodiment, the memory device 100 may operate in a single level cell (SLC) method by which a single data bit is stored in a single memory cell, or by a method of storing at least two data bits in a single memory cell. For example, the memory device 100 may operate by a multi-level cell (MLC) method of storing two data bits in a single memory cell, a triple level cell (TLC) method of storing three data bits, or a quadruple level cell (QLC) method of storing four data bits.

The memory device 100 may receive a command and an address from the memory controller 200, and access a region selected in response to the address in the memory cell array. That is, the memory device 100 may perform an operation corresponding to the command on the area selected in response to the address. For example, the memory device 100 may perform a write operation (program operation), a read operation, or an erase operation in response to a received command. For example, when receiving a program command, the memory device 100 may program a region selected by an address with data. For example, when receiving a read command, the memory device 100 may read data from the area selected by the address. For example, when receiving an erase command, the memory device 100 may erase data from the area selected by the address.

The memory controller 200 may control general operation of the storage device 50.

When a power voltage is applied to the storage device 50, the memory controller 200 may execute firmware. When the memory device 100 is a flash memory device, the memory controller 200 may execute firmware such as a Flash Translation Layer (FTL) for controlling communication between the host 300 and the memory device 100.

According to an embodiment, the memory controller 200 may include firmware (not shown) which receives data and a logical block address LBA from the host 300 and converts the logical block address LBA into a physical block address PBA indicating an address of memory cells in which data in the memory device 100 is stored. In addition, the memory controller 200 may store a logical-physical address mapping table configuring a mapping relationship between the logical block address LBA and the physical block address PBA in a buffer memory.

For example, the memory controller 200 may control the memory device 100 so that a program operation, a read operation, or an erase operation may be performed in response to a request from the host 300. For example, when receiving a program request from the host 300, the memory controller 200 may change the program request into a program command, and provide the program command, the physical block address PBA and data to the memory device 100. When receiving a read request along with the logical block address from the host 300, the memory controller 200 may change the read request into a read command, select a physical block address corresponding to the logical block address, and provide the read command and the physical block address PBA to the memory device 100. When receiving a read request along with the logical block address from the host 300, the memory controller 200 may change the read request into a read command, select a physical block address corresponding to the logical block address, and provide the read command and the physical block address PBA to the memory device 100.

According to an embodiment, the memory controller 200 may generate and transfer a program command, an address, and data to the memory device 100 without a request from the host 300. For example, the memory controller 200 may provide a command, an address, and data to the memory device 100 to perform background operations, such as a program operation for wear leveling and a program operation for garbage collection.

According to an embodiment, the memory controller 200 may include a stream ID controller 210. The stream ID controller 210 may receive update data for updating data stored in the memory device 100 from the host 300. The stream ID controller 210 may generate new program data in which a stream ID is assigned to the received update data.

For example, the stream ID controller 210 may count the number of times that a logical block address is received together with the update data from the host 300 for programming of the update data and the number of times that a garbage collection is performed on data corresponding to the received logical block address. The number of times that the logical block address is received from the host 300 may represent the number of times that the data corresponding to the received logical block address is updated. The number of times that the garbage collection is performed may represent the number of times that the data corresponding to the received logical block address is moved to another memory block without update.

In other words, when the number of logical block addresses received from the host 300 increases, it may mean that the data corresponding to the received logical block address is relatively frequently updated. In addition, when the number of times that the garbage collection is performed increases, it may mean that the data corresponding to the received logical block address is not updated very often.

The memory controller 200 may include a flash transition layer 220. The flash transition layer 220 may convert the logical block address received from the host 300 into a physical block address. In other words, the flash transition layer 220 may generate a mapping relationship between the logical block address and the physical block address. In other words, the flash transition layer 220 may map the logical block address to the physical block address.

The flash transition layer 220 may establish a mapping relationship with reference to host data received from the host 300. For example, the mapping relationship may be established on the basis of the stream ID included in the host data. In other words, the flash transition layer 220 may establish a mapping relationship so that the corresponding host data may be stored in a region corresponding to the stream ID.

According to an embodiment, when the flash transition layer 220 receives new program data from the stream ID controller 210, the flash transition layer 220 may generate a mapping relationship on the basis of a stream ID of the new program data. In other words, the flash transition layer 220 may map a logical block address to a physical block address on the basis of the stream ID of the new program data.

The memory controller 200 may include a request controller 230. The request controller 230 may receive a program request and program data from the host 300 and output a program command and program data corresponding to the program request to the memory device 100. The memory device 100 may perform a program operation in response to the program command.

According to an embodiment, after the request controller 230 outputs the program command for storing the update data received from the host 300, the request controller 230 may invalidate the mapping relationship with respect to the data before the update.

According to an embodiment, the storage device 50 may further include a buffer memory (not shown). The memory controller 200 may control data exchange between the host 300 and the buffer memory (not shown). Alternatively, the memory controller 200 may temporarily store system data for controlling the memory device 100. For example, the memory controller 200 may temporarily store data input from the host 300 in the buffer memory and transfer the data temporarily stored in the buffer memory to the memory device 100.

According to various embodiments, the buffer memory may serve as an operation memory or a cache memory of the memory controller 200. The buffer memory may store codes or commands executed by the memory controller 200. Alternatively, the buffer memory may store data processed by the memory controller 200.

According to an embodiment, the buffer memory may include a dynamic random access memory (DRAM), such as Double Data Rate Synchronous Dynamic Random Access Memory (DDR SDRAM), Low Power Double Data Rate4 (LPDDR4) SDRAM, Graphics Double Data Rate (GDDR) SDRAM, Low Power DDR (LPDDR), or Rambus Dynamic Random Access Memory (RDRAM), or a static random access memory (SRAM).

According to various embodiments, the buffer memory may be externally coupled to the storage device 50. In this case, the buffer memory may be realized by one or more nonvolatile memory devices externally coupled to the storage device 50.

According to an embodiment, the memory controller 200 may control at least two memory devices. The memory controller 200 may control these memory devices according to an interleaving scheme so as to improve operation performance.

The host 300 may communicate with the storage device 50 using at least one of various communication methods such as Universal Serial Bus (USB), Serial AT Attachment (SATA), Serial Attached SCSI (SAS), High Speed Interchip (HSIC), Small Computer System Interface (SCSI), Peripheral Component Interconnection (PCI), PCI express (PCIe), Nonvolatile Memory express (NVMe), Universal Flash Storage (UFS), Secure Digital (SD), MultiMedia Card (MMC), embedded MMC (eMMC), Dual In-line Memory Module (DIMM), Registered DIMM (RDIMM), and/or Load Reduced DIMM (LRDIMM) communication methods.

The host 300 may include a file system 310. The file system 310 may include a stream ID in host data output by the host 300. For example, the file system 310 may assign a stream ID.

The file system 310 may transfer the host data, to which the stream ID is assigned, to the memory controller 200.

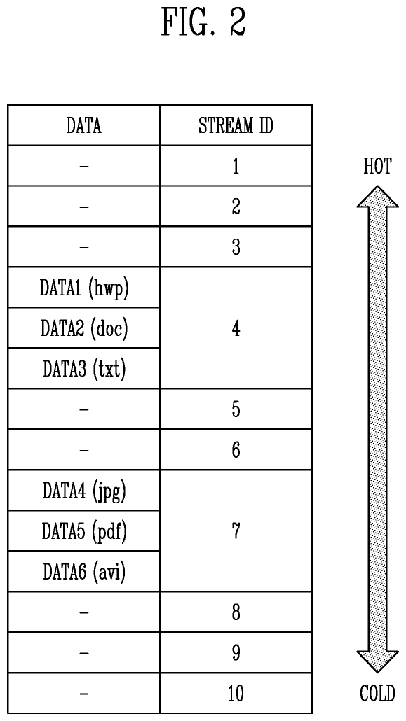

FIG. 2 is a diagram illustrating a stream ID assigned to host data.

FIG. 2 illustrates a stream ID (STREAM ID) assigned by the file system 310 in the host 300 of FIG. 1. The stream ID may be a number from 1 to 10. According to an embodiment, a stream ID closer to 1, may indicate that the corresponding data is frequently updated (HOT). On the other hand, a stream ID closer to 10, may indicate that the corresponding data is not frequently updated (COLD).

The scale of 1 to 10 is exemplary. In another embodiment, the stream ID may be selected from a narrower range (e.g., 1 to 5) or a wider range (e.g., 1 to 15) than the range from 1 to 10.

In the embodiment of FIG. 2, the data output from the host 300 may include first to sixth data DATA1 to DATA6, each being a piece of data.

According to an embodiment, the file system 310 may assign an initial stream ID of 4 or 7 to each piece of data. For example, when it is expected that the corresponding piece of data will be frequently updated (HOT), the file system 310 may assign a stream ID of 4 to that data. However, when it is expected that the corresponding piece of data will not be frequently updated (COLD), the file system 310 may assign a stream ID of 7 to that data. Whether or not the corresponding data is frequently updated may be determined based on a data extension or a data file format.

For example, when the extension of the data output from the host 300 of FIG. 1 is txt, doc, docx, or hwp, the file system may assign a stream ID of 4. For example, when the extension of the data is jpg, jpeg, mp4, pdf, or avi, the file system may assign a stream ID of 7. In other words, the file system may determine whether or not data update frequently occurs on the basis of the extension of the data, and may assign a stream ID to the data based on the determination.

According to an embodiment, when the extension of the data is txt, doc, docx, or hwp, the corresponding data may contain a file containing text and be subject to frequent changes. Thus, it is expected that the corresponding data may be frequently updated. Therefore, the file system 310 may assign a stream ID of 4 to the data.

In addition, when the extension of the data is jpg, jpeg, mp4, pdf, or avi, the corresponding data may be an image file or a video file. Once this type of data is generated, it may not be changed, and it is expected that the corresponding data may not be frequently updated. Therefore, the file system 310 may assign a stream ID of 7.

In another example, when the data output from the host 300 of FIG. 1 is a text file, the file system 310 may assign a stream ID of 4 to the data of the text file. When the data output from the host 300 of FIG. 1 is an image file or a video file, the file system 310 may assign a stream ID of 7 to the data of the image or video file. In other words, the file system 310 may determine whether or not data update frequently occurs on the basis of characteristics of the data, and may assign a stream ID to the data based on the determination.

According to an embodiment, when the file format of the data is a text file, the data may be subject to frequent changes. Thus, it is expected that the data may be frequently updated. Therefore, the file system may assign a stream ID of 4.

In addition, when the file format of the data is an image file or a video file, the data may not be changed. Thus, it is expected that the data may not be frequently updated. Therefore, the file system may assign a stream ID of 7.

FIG. 2 illustrates a stream ID (STREAM ID) assigned to each piece of data based on a data extension.

According to an embodiment, the first data DATA1 may be have an hwp file extension. In other words, the first data DATA1 may contain text, and thus it is expected that the first data DATA1 may be frequently updated. Therefore, the file system 310 may assign a stream ID of 4 to the first data DATA1.

In the same manner, the second data DATA2 may have a doc file extension and the third data DATA3 may have a txt file extension. Thus, both the second and third data DATA2 and DATA3 may be text files and expected to be frequently updated. Therefore, the file system 310 may assign a stream ID of 4 to each of the second and third data DATA2 and DATA3.

According to an embodiment, the fourth data DATA4 may refer to a file with a jpg file extension. In other words, the fourth data DATA4 may be image data, and thus, it is expected that the corresponding data may not be frequently updated. Therefore, the file system may assign a stream ID of 7 to the fourth data DATA4.

In the same manner, the fifth data DATA5 may have a pdf extension and the sixth data DATA6 may have an avi file extension. Thus, both the fifth and sixth data DATA5 and DATA6 may be an image file by imaging text, and a video file, respectively, and may be expected not to be frequently updated. Therefore, the file system 310 may assign a stream ID of 7 to each of the fifth and sixth data DATA5 and DATA6.

As a result, the host 300 may assign a stream ID to data which is output from the host 300, and the stream ID of 4 or 7 may be assigned to the data. In addition, whether the stream ID is 4 or 7 may be determined by a data extension or data characteristics.

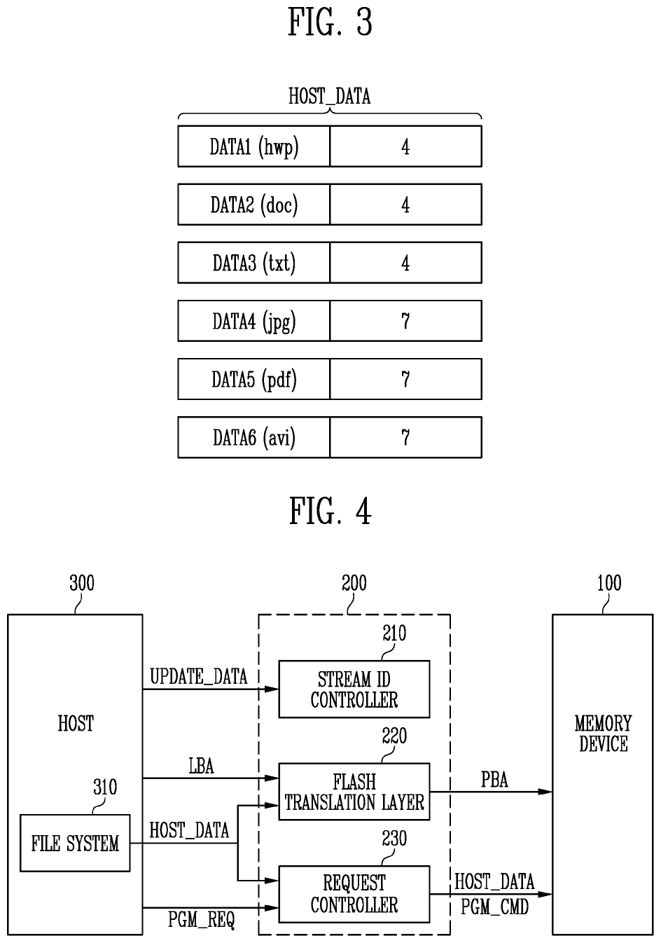

FIG. 3 is a diagram illustrating pieces of host data to which stream IDs are assigned.

Referring to FIGS. 2 and 3, FIG. 3 illustrates host data (HOST_DATA) output from the host 300 of FIG. 1. The host data may include pieces of data each having a stream ID.

It may be assumed that first to sixth data DATA1 to DATA6 of FIG. 3 are the same as the first to sixth data DATA1 to DATA6 of FIG. 2, respectively.

According to an embodiment, the host data HOST_DATA output from the host 300 may include the first data DATA1 with a stream ID of 4. Each piece of host data may be stored in the memory device 100 of FIG. 1 on the basis of its stream ID included in the corresponding data. For example, when a stream ID of 4 is included in a piece of data, that data may be stored in a region of the memory device 100 corresponding to stream ID of 4.

According to an embodiment, the host data output from the host 300 may include the second data DATA2 with the stream ID of 4, and/or the third data DATA3 with the stream ID of 4. Since the stream ID included in the DATA2 is 4, that data may be stored in a region of the memory device 100 corresponding to a stream ID of 4.

In addition, the host data output from the host 300 may include the fourth data DATA4 with the stream ID of 7, the fifth data DATA5 with the stream ID of 7, and/or the sixth data DATA6 with the stream ID of 7. Since each of these pieces of data has a stream ID of 7, each piece may be stored in a region of the memory device 100 corresponding to the received stream ID.

FIG. 4 is a diagram illustrating a configuration of a memory controller 200 receiving a request, an address and data from the host 300, and storing the received data in a memory device.

Referring to FIG. 4, the memory controller 200 may include the stream ID controller 210, the flash transition layer 220 and the request controller 230. The host 300 may include the file system 310.

According to an embodiment, the file system 310 may assign a stream ID to specific data. The stream ID may be determined depending on a data extension, or a file format of the data. The file system 310 may transfer each piece of data to which the stream ID is assigned to the memory controller 200. For example, each piece of data may be output to the flash transition layer 220 and the request controller 230 of the memory controller 200.

The host 300 may output the logical block address LBA and a program request PGM_REQ along with a particular piece of host data to the memory controller 200 in order to program such data in the memory device 100. The logical block address LBA may be output to the flash transition layer 220 and the program request PGM_REQ may be output to the request controller 230.

According to an embodiment, the flash transition layer 220 may receive the logical block address LBA and the host data from the host 300.

In other words, the flash transition layer 220 may generate a mapping relationship between the logical block address LBA and the physical block address PBA. More specifically, the flash transition layer 220 may generate the mapping relationship with reference to the stream ID of a piece of host data. In other words, the flash transition layer 220 may generate the mapping relationship with reference to the stream ID so that the piece of host data may be stored in a region corresponding to its stream ID.

For example, when the stream ID is 4, a mapping relationship may be configured so that the corresponding host data may be stored in a region (e.g., a fourth region among first to tenth regions) in which data each having a stream ID of 4 is stored, among a plurality of regions of the memory device 100. In addition, when the stream ID is 7, a mapping relationship may be configured so that the corresponding host data may be stored in a region (e.g., a seventh region among the first to tenth regions) in which data each having a stream ID of 7 is stored, among the plurality of regions of the memory device 100.

The flash transition layer 220 may generate a mapping relationship on the basis of the stream ID and output the physical block address PBA to the memory device 100 on the basis of the generated mapping relationship. In other words, the flash transition layer 220 may map a logical block address to a physical block address on the basis of a stream ID.

According to an embodiment, the request controller 230 may receive the program request PGM_REQ and the host data HOST_DATA. The program request PGM_REQ may instruct that the corresponding piece of host data be stored in the memory device 100.

The request controller 230 may output a program command PGM_CMD and the host data to the memory device 100 so as to store the host data in the memory device 100.

According to an embodiment, after the memory device 100 receives the program command PGM_CMD, the physical block address PBA and the host data, the memory device 100 may program the host data into a region of the memory device 100 corresponding to the physical block address PBA.

As a result, the file system 310 may initially assign a stream ID to data of ‘4 (HOT)’ or ‘7 (COLD)’. Thus, the stream ID included in each piece of host data may be 4 or 7. Therefore, initially, the host data HOST_DATA may be stored in only regions corresponding to the stream ID of 4 or 7 among the plurality of regions of the memory device 100.

According to an embodiment, the stream ID controller 210 may receive update data UPDATE_DATA. In other words, the stream ID controller 210 may receive data for updating the data stored in the memory device 100.

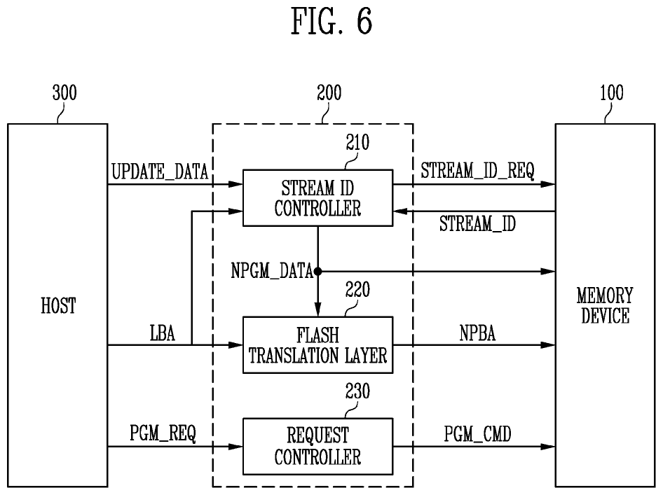

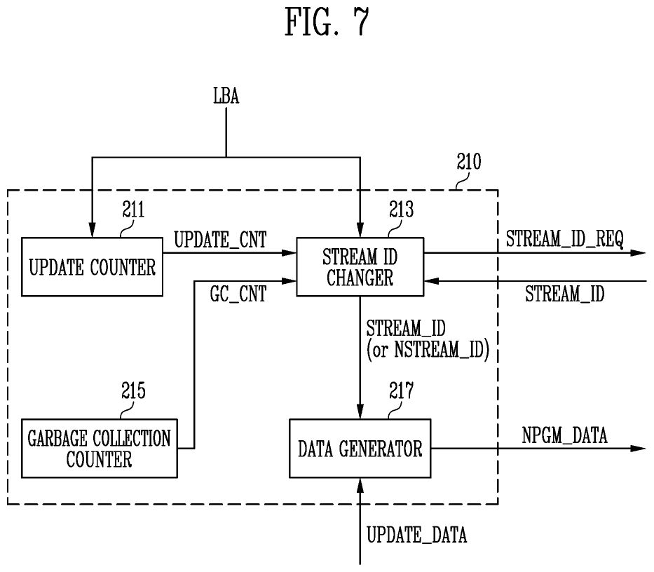

Operations performed after the stream ID controller 210 receives the update data are described below in more detail with reference to FIGS. 6 and 7.

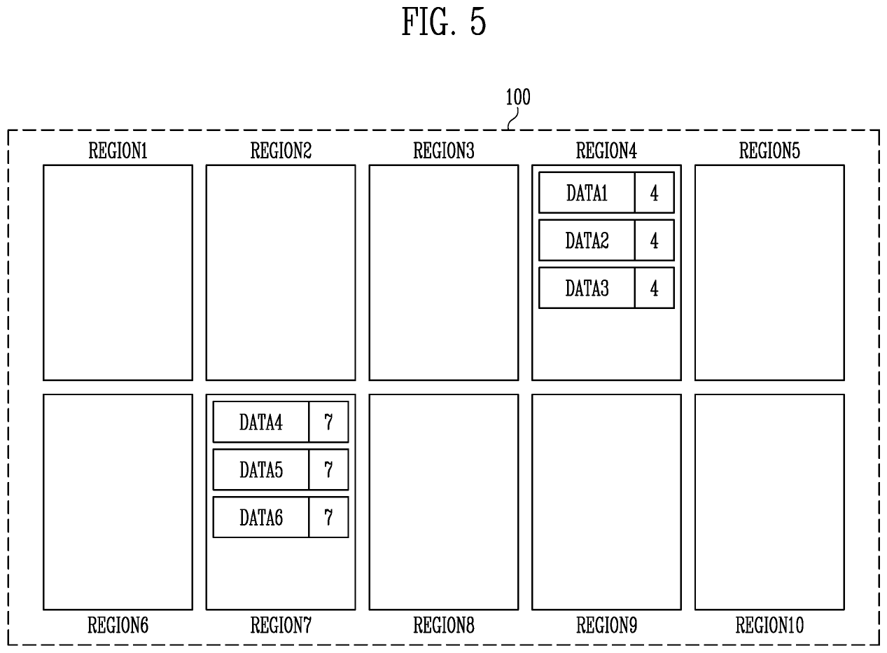

FIG. 5 illustrates data stored in the memory device 100 based on an initial stream ID.

Referring to FIG. 5, FIG. 5 illustrates data stored in a set region, among a plurality of regions included in the memory device 100 of FIG. 1. As shown in FIG. 5, the memory device 100 of FIG. 1 may include first to tenth regions REGION1 to REGION10. However, in other embodiments, the memory device 100 of FIG. 1 may have fewer or more regions. Each of the first to tenth regions REGION1 to REGION10 may include a plurality of memory blocks.

It may be assumed that first to sixth data DATA1 to DATA6 of FIG. 5 are the same as the first to sixth data DATA1 to DATA6 of FIGS. 2 and 3, respectively.

According to an embodiment, the first to tenth regions REGION1 to REGION10 may correspond to regions having stream IDs of 1 to 10, respectively. In other words, the first region REGION1 may correspond to the stream ID of 1, the second region REGION2 may correspond to the stream ID of 2, the third region REGION3 may correspond to the stream ID of 3, the fourth region REGION4 may correspond to the stream ID of 4, the fifth region REGIONS may correspond to the stream ID of 5, the sixth region REGION6 may correspond to the stream ID of 6, the seventh region REGION7 may correspond to the stream ID of 7, the eighth region REGION8 may correspond to the stream ID of 8, the ninth region REGIONS may correspond to the stream ID of 9, and the tenth region REGION10 may correspond to the stream ID of 10.

According to an embodiment, host data initially received from the host 300 of FIG. 1 may have a stream ID of 4 or 7. In other words, the stream ID of the host data may be initially determined as 4 or 7 on the basis of a data extension or a file format of the data. Therefore, the host data received from the host 300 may be stored in regions corresponding to the stream ID of 4 or 7, among the plurality of regions of the memory device 100 of FIG. 1.

According to an embodiment, the stream ID corresponding to each of the first to third data DATA1 to DATA3 may be 4. Therefore, when the memory device 100 of FIG. 1 receives the first data DATA1 and the stream ID of 4, the memory device 100 may store that data in the fourth region REGION4. In the same manner, when the memory device 100 receives the second data DATA2 and the stream ID of 4, or the third data DATA3 and the stream ID of 4, the memory device 100 may store each of those pieces of data in the fourth region REGION4.

According to an embodiment, the stream ID corresponding to each of the fourth to sixth data DATA4 to DATA6 may be 7. Therefore, when the memory device 100 of FIG. 1 receives the fourth data DATA4 and the stream ID of 7, the memory device 100 may store that data in the seventh region REGION7. In the same manner, when the memory device 100 receives the fifth data DATA5 and the stream ID of 7, and/or the sixth data DATA6 and the stream ID of 7, the memory device 100 may store the corresponding data in the seventh region REGION7.

Therefore, since the initial stream ID is set to 4 or 7, each piece of host data may be stored in only the fourth region REGION4 or the seventh region REGION7 corresponding to the stream ID of 4 or 7, whereas data may not be stored in any of the other regions, i.e., REGION1 to REGION3, REGION5, REGION6 and REGION8 to REGION10.

FIG. 6 is a diagram illustrating operations of the memory controller 200 after update data is received from the host 300.

Referring to FIG. 6, the memory controller 200 may be configured the same as the memory controller of FIG. 4. To that end, the memory controller 200 of FIG. 6 may include the stream ID controller 210, the flash transition layer 220 and the request controller 230.

FIG. 6 illustrates operations performed after host data is stored in the fourth and seventh regions among the regions included in the memory device 100. In other words, FIG. 6 illustrates that data of fourth to seventh regions are updated.

According to an embodiment, the host 300 may output the update data UPDATE_DATA for updating the data stored in the memory device 100 to the memory controller 200. In addition, the host 300 may output the program request PGM_REQ and the logical block address LBA, together with the update data, to the memory controller 200.

According to an embodiment, the stream ID controller 210 may receive the update data and the logical block address LBA output from the host 300. The stream ID controller 210 may output a stream ID request STREAM_ID_REQ to the memory device 100 to assign a stream ID to the update data. The stream ID request STREAM_ID_REQ may be for acquiring a stream ID (STREAM_ID) of data stored in the physical block address having a mapping relationship with the received logical block address LBA.

The stream ID controller 210 may maintain, increase, or reduce the stream ID received in response to the stream ID request STREAM_ID_REQ.

For example, the stream ID controller 210 may maintain, i.e., not change, the stream ID when the number of times a particular logical block address is received is less than a first reference number, or when the number of times that a garbage collection is performed on the particular logical block address is less than a second reference number.

For example, when the particular logical block address has been received the first reference number or more, the stream ID controller 210 may reduce the stream ID. In addition, when garbage collection is performed on the particular logical block address the second reference number of times or more, the stream ID controller 210 may increase the stream ID. In other words, when either or both of these conditions occur, the stream ID controller 210 may not use the fixed stream ID, and instead may change the stream ID.

Subsequently, the stream ID controller 210 may generate new program data NPGM_DATA to which a stream ID, which may be the same or different than that of the initial data, is assigned. The new program data NPGM_DATA may be output to the flash transition layer 220 and the memory device 100.

According to an embodiment, the flash transition layer 220 may receive the logical block address LBA from the host 300 and the new program data NPGM_DATA from the stream ID controller 210. The flash transition layer 220 may generate a mapping relationship between the received logical block address LBA and a new physical block address NPBA with reference to the stream ID of the new program data NPGM_DATA. In other words, the flash transition layer 220 may generate a mapping relationship so that the new program data NPGM_DATA may be stored in a region of the memory device 100 corresponding to the changed stream ID, i.e., a region corresponding to the new physical block address NPBA. In other words, the flash transition layer 220 may map a logical block address to a physical block address on the basis of the changed stream ID.

The flash transition layer 220 may output the new physical block address NPBA to the memory device 100 after generating the mapping relationship between the logical block address LBA and the physical block address PBA. When the stream ID is not changed, the physical block address PBA the same as before may be output on the basis of the existing mapping relationship between the logical block address LBA and the physical block address PBA. However, when the stream ID is changed, the new physical block address NPBA may be output.

For example, when the stream ID changes from 4 to 3, the flash transition layer 220 may output the new physical block address NPBA to the memory device 100 so that the update data UPDATE_DATA may be stored in a region corresponding to the stream ID of 3.

According to an embodiment, the request controller 230 may receive the program request PGM_REQ from the host 300, generate the program command PGM_CMD corresponding to the program request PGM_REQ, and output the program command PGM_CMD to the memory device 100. The program command PGM_CMD may instruct the memory device 100 to program the update data UPDATE_DATA.

When the update data UPDATE_DATA is programmed into the new physical block address NPBA, the request controller 230 may invalidate the mapping relationship with respect the corresponding piece of host data before the update.

FIG. 7 illustrates operations performed by the stream ID controller 210 by receiving update data from the host 300 and outputting new program data.

Referring to FIG. 7, the stream ID controller 210 of FIG. 7 may include an update counter 211, a stream ID changer 213, a garbage collection counter 215, and a data generator 217.

FIG. 7 illustrates that the new program data NPGM_DATA is output after the host data is stored in the fourth and seventh regions among the plurality of regions included in the memory device 100.

According to an embodiment, the stream ID controller 210 may receive the logical block address LBA output from the host 300. The logical block address LBA received from the host 300 may be provided to the update counter 211 and the stream ID changer 213.

According to an embodiment, the update counter 211 may count the logical block addresses LBA received from the host 300. The update counter 211 may count the received logical block addresses LBA only when the host data as well as the logical block addresses LBA is received from the memory controller 200 of FIG. 6. In other words, the update counter 211 may count the number of times that the logical block address LBA is received only when the logical block address LBA corresponding to the program request is received. The program request may be output to update the data stored in the memory device 100.

Therefore, the update counter 211 may count the number of times that the corresponding logical block address LBA is received whenever the data corresponding to the logical block address LBA is updated. The update counter 211 may count the number of times that the corresponding logical block address LBA is received, generate an update count UPDATE_CNT, and provide the update count UPDATE_CNT to the stream ID changer 213.

According to an embodiment, the garbage collection counter 215 may count the number of times that the data stored in the physical block address PBA corresponding to the logical block address LBA is moved to another memory block without update through garbage collection. In other words, the garbage collection counter 215 may generate a garbage collection count GC_CNT by counting the number of times that the data is moved to another memory block without update by garbage collection.

According to an embodiment, the stream ID controller 210 may receive the logical block address LBA output from the host 300. The stream ID changer 213 may output the stream ID request STREAM_ID_REQ to the memory device 100 in order to check the stream ID corresponding to the logical block address LBA. Subsequently, the stream ID changer 213 may receive the stream ID corresponding to the stream ID request STREAM_ID_REQ.

According to an embodiment, when the update count UPDATE_CNT received from the update counter 211 is less than a first reference value and the garbage collection count GC_CNT is less than a second reference value, the stream ID changer 213 may not change the stream ID of the data corresponding to the logical block address LBA received from the host 300 of FIG. 6. The stream ID changer 213 may output the existing stream ID received from the memory device 100 of FIG. 6 to the data generator 217.

However, when the update count UPDATE_CNT received from the update counter 211 is the first reference value or more, or the garbage collection count GC_CNT received from the garbage collection counter 215 is the second reference value or more, the stream ID changer 213 may output a new stream ID NSTREAM_ID obtained by increasing or decreasing the initial stream ID.

According to an embodiment, the first reference value and the second reference value may be 10.

For example, when the number of times that the logical block address LBA is received is 10 or more, the update count UPDATE_CNT may be 10 or more. Therefore, after receiving the update count UPDATE_CNT, the stream ID changer 213 may decrease the stream ID. In addition, when the number of garbage collection is 10 or more, the garbage collection count GC_CNT may be 10 or more. Therefore, after receiving the garbage collection count GC_CNT, the stream ID changer 213 may increase the stream ID.

According to an embodiment, when the update count UPDATE_CNT is 10 or more, the stream ID changer 213 may reduce the stream ID received from the memory device 100 by 1. For example, the stream ID received from the memory device 100 is 4, the stream ID changer 213 may receive the update count UPDATE_CNT and reduce the stream ID to 3.

According to an embodiment, when the garbage collection count GC_CNT is 10 or more, the stream ID changer 213 may increase the stream ID received from the memory device 100 by 1. For example, the stream ID received from the memory device 100 is 4, the stream ID changer 213 may receive the garbage collection count GC_CNT and increase the stream ID to 5.

In another embodiment, when the stream ID changer 213 receives both the update count UPDATE_CNT of 10 or more from the update counter 211 and the garbage collection count GC_CNT of 10 or more from the garbage collection counter 215, the stream ID changer 213 may not change the stream ID.

According to an embodiment, the stream ID changer 213 may output the new stream ID NSTREAM_ID by increasing or decreasing the stream ID, or may output the existing stream ID. The new stream ID NSTREAM_ID or the existing stream ID may be provided to the data generator 217.

The data generator 217 may receive the update data UPDATE_DATA from the host 300, generate the new program data NPGM_DATA in which the existing stream ID or the new stream ID NSTREAM_ID is assigned to the update data UPDATE_DATA, and may output the new program data NPGM_DATA to the memory device 100.

In other words, when the stream ID is not changed, the data generator 217 may generate the new program data NPGM_DATA in which the existing stream ID is assigned to the update data UPDATE_DATA. On the other hand, when the stream ID is changed, the data generator 217 may generate the new program data NPGM_DATA in which the new stream ID NSTREAM_ID is assigned to the update data UPDATE_DATA.

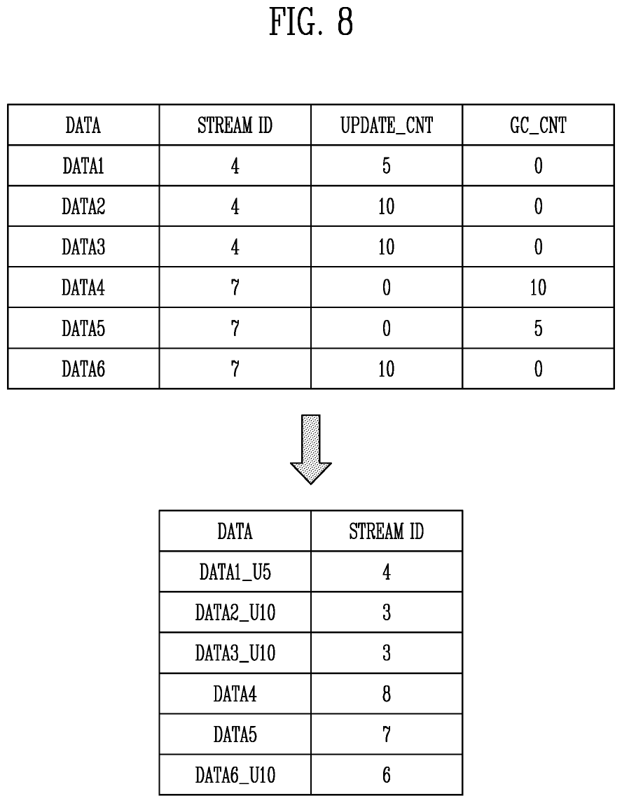

FIG. 8 is a diagram illustrating maintaining or changing a stream ID (STREAM ID).

As shown in FIG. 8, the stream ID assigned to the first to sixth data DATA1 to DATA6 may be maintained or changed. Initially, the stream ID assigned to each of the first to third data DATA1 to DATA3 is 4 and the stream ID assigned to each of the fourth to sixth data DATA4 to DATA6 is 7.

In other words, initially, since it is expected that the first to third data DATA1 to DATA3 will be frequently updated, the stream ID of each of the first to third data DATA1 to DATA3 may be assigned as 4. On the other hand, since it is expected that the fourth to sixth data DATA4 to DATA6 will not be frequently updated, the stream ID of each of the fourth to sixth data DATA4 to DATA6 may be assigned as 7.

As in the example of FIG. 7, in FIG. 8, each of the first and second reference values used to determine whether the stream ID is to be changed is 10. In another embodiment, each of the first and second reference values may be different than 10 and may not necessarily be the same.

According to an embodiment, the stream ID of each of the first to sixth data DATA1 to DATA6 may be changed based on data update and garbage collection GC.

According to an embodiment, after the initial stream ID of the first data DATA1 is set, the first data DATA1 may be updated five times by the garbage collection GC without being moved to another memory block. In other words, the update count UPDATE_CNT counted by the update counter 211 may be 5, and the garbage collection count GC_CNT counted by the garbage collection counter 215 may be 0.

Since the update count UPDATE_CNT is less than the first reference value of 10 and the garbage collection count GC_CNT is less than the second reference value of 10, the stream ID changer 213 may maintain the existing stream ID of the first data DATA1. Therefore, the stream ID of the first data DATA1 may remain at 4.

As a result, since the first data DATA1 is updated five times, the existing stream ID of 4 may be assigned to the updated first data DATA1_U5, and new program data including the first data DATA1_U5 and the stream ID of 4 may be stored in the fourth region corresponding to the stream ID of 4, among the regions of the memory device 100 of FIG. 1.

According to an embodiment, after the initial stream ID of the second and third data DATA2 and DATA3 is set, the second and third data DATA2 and DATA3 may be updated ten times by the garbage collection GC without being moved to another memory block. In other words, the update count UPDATE_CNT counted by the update counter 211 is 10, and the garbage collection count GC_CNT counted by the garbage collection counter 215 may be 0.

Thus, the update count UPDATE_CNT for each of DATA2 and DATA3 is the first reference value of 10, while the garbage collection GC_CNT of each is less than the second reference value. Therefore, the stream ID changer 213 may reduce the stream ID of the second and third data DATA2 and DATA3. In other words, to show that the second and third data DATA2 and DATA3 are frequently updated, the stream ID changer 213 may reduce the stream ID of each of the second and third data DATA2 and DATA3 from 4 to 3.

As a result, the changed stream ID of 3 may be assigned to each of the updated second data and third data DATA2_U10 and DATA3_U10, and new program data including the updated second data DATA2_U10 and the stream ID of 3 and new program data including the updated third data DATA3_U10 and the stream ID of 3 may be stored in the third region corresponding to the stream ID of 3, among the regions of the memory device 100.

According to an embodiment, after the initial stream ID of the fourth data DATA4 is set, the fourth data DATA4 may be moved to another memory block ten times by the garbage collection GC without updating the fourth data DATA4. In other words, the update count UPDATE_CNT counted by the update counter 211 may be 0, and the garbage collection count GC_CNT counted by the garbage collection counter 215 may be 10.

The second reference value of the garbage collection count GC_CNT may be 10 or more, whereas the first reference value of the update count UPDATE_CNT may be less than 10. Therefore, since the number of times that a garbage collection is performed is the second reference value or more, the stream ID changer 213 may reduce the stream ID of the fourth data DATA4. In other words, to show that the fourth data DATA4 is not frequently updated, the stream ID changer 213 may increase the stream ID of each of the fourth data DATA4 from 7 to 8.

As a result, since the fourth data DATA4 is updated ten times, the changed stream ID of 8 may be assigned to the fourth data DATA4, and new program data including the fourth data DATA4 and the stream ID of 8 may be stored in the third region corresponding to the stream ID of 8, among the regions of the memory device 100.

According to an embodiment, after the initial stream ID of the fifth data DATA5 is set, the fifth data DATA5 may be moved to another memory block five times by the garbage collection GC without updating the fifth data DATA5. In other words, the update count UPDATE_CNT counted by the update counter 211 may be 0, and the garbage collection count GC_CNT counted by the garbage collection counter 215 may be 5.

The second reference value of the garbage collection count GC_CNT may be less than 10, whereas the first reference value of the update count UPDATE_CNT may be less than 10. Therefore, since the garbage collection count GC_CNT or the update count UPDATE_CNT fails to reach the second reference value, the stream ID changer 213 may maintain the stream ID of 7 for the fifth data DATA5.

As a result, since the fifth data DATA5 is updated five times, the existing stream ID of 7 may be assigned to the fifth data DATA5, and new program data including the fifth data DATA5 and the stream ID of 7 may be stored in the seventh region corresponding to the stream ID of 7, among the plurality of regions of the memory device 100.

According to an embodiment, after the initial stream ID of the sixth data DATA6 is set, the sixth data DATA6 may be updated ten times by the garbage collection GC without being moved to another memory block. In other words, the update count UPDATE_CNT counted by the update counter 211 may be 10, and the garbage collection count GC_CNT counted by the garbage collection counter 215 may be 0.

The update count UPDATE_CNT may have the first reference value of 10 or more. However, the garbage collection count GC_CNT may be less than the second reference value of 10. Therefore, since the number of times that the sixth data DATA6 is updated is more than the first reference value, the stream ID changer 213 may reduce the stream ID of the sixth data DATA6. In other words, to show that the sixth data DATA6 is frequently updated, the stream ID changer 213 may reduce the stream ID of the sixth data DATA6 from 7 to 6.

As a result, since the sixth data DATA6 is updated ten times, the changed stream ID of 6 may be assigned to updated sixth data DATA6_U10, and new program data including the updated sixth data DATA6_U10 and the stream ID of 6 may be stored in the fourth region corresponding to the stream ID of 6, among the plurality of regions of the memory device 100.

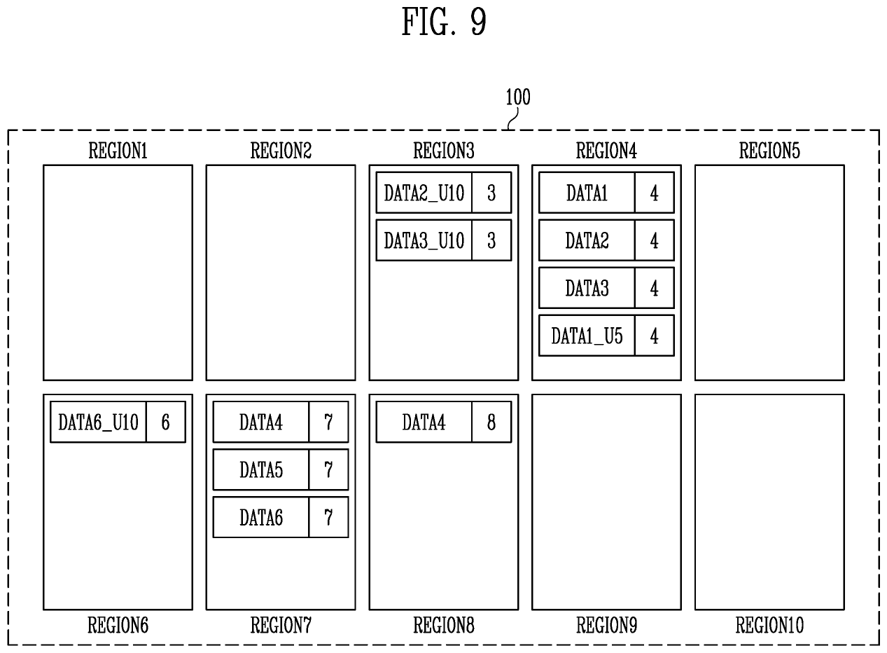

FIG. 9 illustrates data stored in the memory device 100 based on the changed initial stream ID.

Referring to FIGS. 5, 8, and 9, FIG. 9 illustrates data stored in another region as the stream ID of data stored in each region is maintained or changed.

As shown in FIG. 9, the memory device 100 depicted therein is the same as the memory device 100 of FIG. 1 and includes the first to tenth regions REGION1 to REGION10. The first to tenth regions REGION1 to REGION10 may include a plurality of memory blocks.

In addition, it may be assumed that the first to sixth data DATA1 to DATA6, the updated first data DATA1_U5, the updated second data DATA2_U10, the updated third data DATA3_U10, and the updated sixth data DATA6_U10 as shown in FIG. 9 are the same as the corresponding data of FIG. 8. In other words, it is assumed that the update count UPDATE_CNT and the garbage collection count GC_CNT of each of the data of FIG. 9 may be the same as those of each of the data of FIG. 8.

According to an embodiment, the initial first to third data DATA1 to DATA3 may be stored in the fourth region REGION4 according to the stream ID assigned to each data, and the initial fourth to sixth data DATA4 to DATA6 may be stored in the seventh region REGION7 according to the stream ID assigned to each data.

Subsequently, the first to sixth data DATA1 to DATA6 may be updated, or the garbage collection GC may be performed.

According to an embodiment, the first data DATA1 may be updated five times and become the updated first data DATA1_U5. However, since the number of times that the first data DATA1 is updated is less than or equal to the first reference value of 10, the stream ID of the updated first data DATA1_U5 may be 4 which corresponds to the stream ID of the first data DATA1. The number of times that the garbage collection is performed on the first data DATA1 may be less than the second reference value of 10.

Therefore, data including the updated first data DATA1_U5 generated by updating the first data DATA1 and the stream ID of 4 may be stored in the fourth region REGION4 corresponding to the stream ID of 4.

According to an embodiment, the second data DATA2 and the third data DATA3 each may be updated ten times and become the updated second data DATA2_U10 and the updated third data DATA3_U10, respectively. Since the number of times that the second and third data DATA2 and DATA3 are updated is the first reference value of 10 or more, the stream ID of the updated second data DATA2_U10 and the updated third data DATA3_U10 may change from 4 to 3. The number of times that the garbage collection is performed on the updated second data DATA2_U10 and the updated third data DATA3_U10 may be less than the second reference value of 10.

Therefore, new program data including the updated second data DATA2_U10 generated by updating the second data DATA2 and the stream ID of 3 and new program data including the updated third data DATA3_U10 generated by updating the third data DATA3 may be stored in the third region REGION3.

According to an embodiment, the fourth data DATA4 may not be updated and the garbage collection may be performed thereon ten times, and it may be stored in another memory block in the fourth region REGION4. Since the number of times that the garbage collection is performed is the second reference value of 10 or more and the number of updates is the first reference value of 10 or less, the stream ID of the fourth data DATA4 may change from 7 to 8. Therefore, new program data including the fourth data DATA4 and the stream ID of 8 may be stored in the eighth region REGION8 corresponding to the stream ID of 8 newly assigned to the fourth data DATA4.

According to an embodiment, the fifth data DATA5 may not be updated and the garbage collection may be performed thereon five times, and it may be stored in another memory block in the fourth region REGION4. Since the number of times that the garbage collection is performed has the second reference value of 10 or less and the number of updates has the first reference value of 10 or less, the stream ID of the fifth data DATA5 may be maintained at 7. Therefore, new program data including the fifth data DATA5 and the stream ID of 7 may be stored in the seventh region REGION7 corresponding to the stream ID of 7.

According to an embodiment, the sixth data DATA6 may be updated ten times and become the updated sixth data DATA6_U10. Since the number of times that the sixth data DATA6 is the first reference value 10 or more, the stream ID of the updated sixth data DATA6_U10 may change from 7 to 6. The number of times that the garbage collection is performed on the updated sixth data DATA6_U10 may be less than the second reference value of 10. Therefore, data including the updated sixth data DATA6_U10 generated by updating the sixth data DATA6 and the stream ID of 6 may be stored in the sixth region REGION6 corresponding to the stream ID of 6.

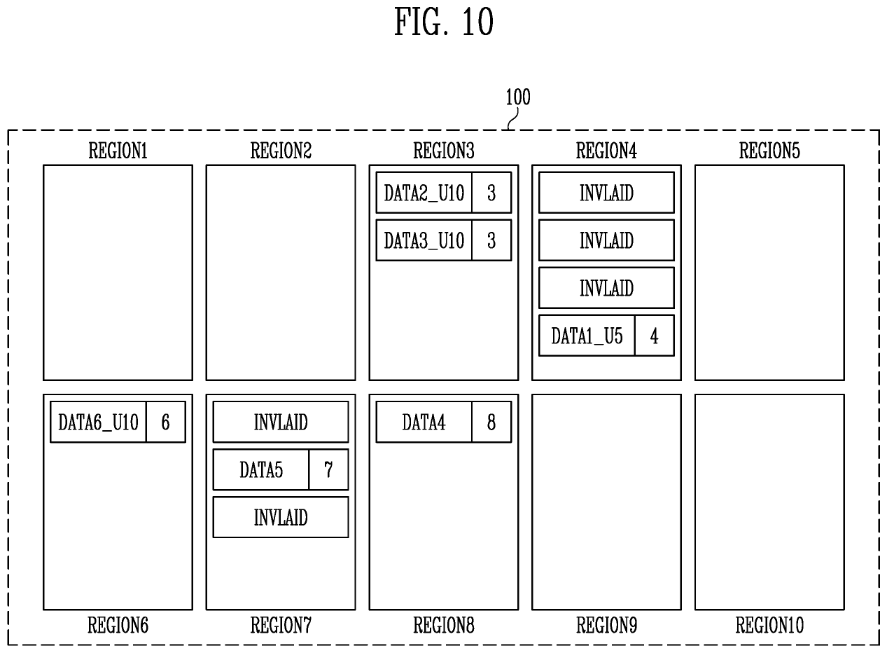

FIG. 10 illustrates data stored in the memory device 100 after the existing mapping relationship is invalidated.

As shown in FIG. 10, data may be stored in each region after the data is moved according to the maintained or changed stream ID as shown in FIG. 9.

According to an embodiment, the memory controller 200 of FIG. 6 may output a program command for programming new program data including updated data and/or the changed stream ID, and may invalidate the existing data stored in the memory device 100.

More specifically, the memory controller 200 may program new program data into the memory device 100, invalidate the mapping relationship between the physical block address and the logical block address corresponding to the existing data, and invalidate the existing data.

According to an embodiment, the first data DATA1 may be updated five times and become the updated first data DATA1_U5, and the updated first data DATA1_U5 may be stored in the fourth region REGION4 according to the stream ID of the updated first data DATA1_U5. Therefore, the memory controller 200 of FIG. 6 may invalidate the mapping relationship between the physical block address and the logical block address corresponding to the first data DATA1 and invalidate the first data DATA1 stored in the fourth region REGION4.

In the same manner, as the second and third data DATA2 and DATA3 are updated, the memory controller 200 may invalidate the mapping relationship between the physical block address and the logical block address corresponding to the second and third data DATA2 and DATA3 stored in the fourth region REGION4, and may invalidate the second and third data DATA2 and DATA3 stored in the fourth region REGION4.

According to an embodiment, since the garbage collection GC is performed on the fourth data DATA4 ten times, the stream ID of the fourth data DATA4 may be 8, and the fourth data DATA4 may be stored in the eighth region REGION8 according to the stream ID of the fourth data DATA4. Therefore, the memory controller 200 of FIG. 6 may invalidate the existing mapping relationship between the physical block address and the logical block address corresponding to the fourth data DATA4 and invalidate the fourth data DATA4 stored in the seventh region REGION7.

According to an embodiment, although the garbage collection is performed on the fifth data DATA5 five times, the stream ID thereof may not be changed. Therefore, since the fifth data DATA5 is stored in another memory block of the fourth region REGION4, the memory controller 200 may neither invalidate the mapping relationship between the physical block address and the logical block address corresponding to the fifth data DATA5 nor invalidate the fifth data DATA5.

According to an embodiment, the sixth data DATA6 may be updated five times and become the updated sixth data DATA6_U10, and the updated sixth data DATA6_U10 may be stored in the sixth region REGION6 according to the stream ID of the updated sixth data DATA6_U10. Therefore, the memory controller 200 may invalidate the mapping relationship between the physical block address and the logical block address corresponding to the sixth data DATA6 and invalidate the sixth data DATA6 stored in the seventh region REGION7.

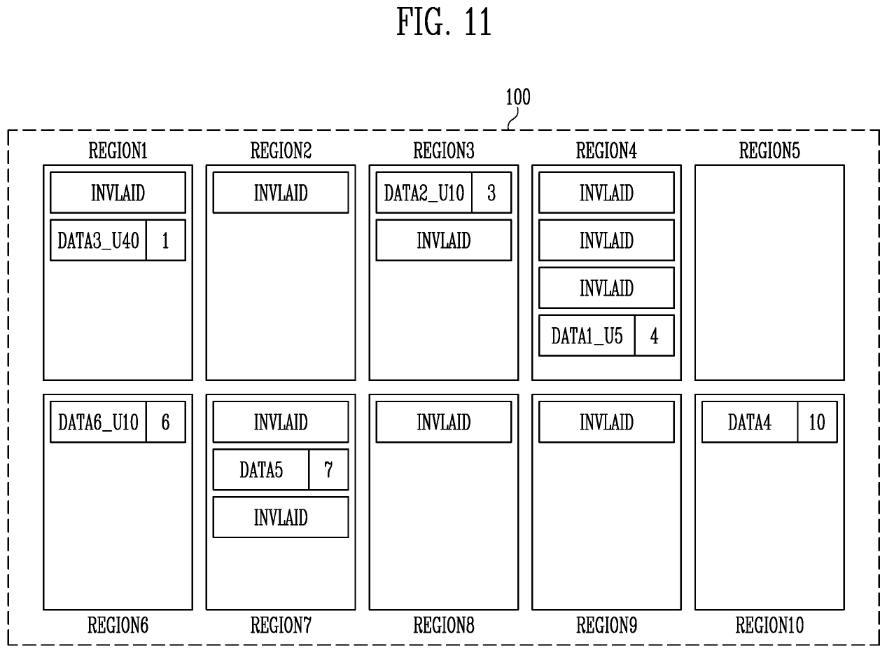

FIG. 11 is a diagram illustrating a stream ID which is changed when the stream ID is 1 or 10.

Referring to FIGS. 10 and 11, FIG. 11 shows that the updated third data DATA3_U10, among the data of FIG. 10, is additionally updated 30 times and the garbage collection GC is additionally performed on the fourth data DATA4 30 times.

In FIG. 11, it may be assumed that the remaining data except for the updated third data DATA3_U10 and the fourth data DATA4 are the same as those of FIG. 10.

According to an embodiment, the updated third data DATA3_U10 stored in the third region REGION3 may be updated. When the updated third data DATA3_U10 stored in the third region REGION3 is updated ten times again, new program data including updated third data DATA3_U20 and the changed stream ID of ‘2’ may be stored in the second region REGION2. The updated third data DATA3_U10 stored in the third region REGION3 may be invalidated.

Subsequently, the updated third data DATA3_U20 stored in the second region REGION2 may be updated ten times. When the updated third data DATA3_U20 is updated ten times again, new program data including updated third data DATA3_U30 and the changed stream ID of 1 may be stored in the first region REGION1. The updated third data DATA3_U20 stored in the second region REGION2 may be invalidated.

Subsequently, the updated third data DATA3_U30 stored in the first region REGION 1 may be updated ten times again. However, since the stream ID of the updated third data DATA3_U30 is 1 and there is no stream ID to be changed, although the updated third data DATA3_U30 is updated, the stream ID of 1 the same as before may be assigned thereto. In other words, when the updated third data DATA3_U30 is updated ten times, new program data including updated third data DATA3_U40 and the existing stream ID of 1 may be stored in the first region REGION 1. The updated third data DATA3_U30 stored in the first region REGION 1 may be invalidated.

According to an embodiment, garbage collection may be performed on the fourth data DATA4 stored in the eighth region REGION8. When the garbage collection is performed on the fourth data DATA4 ten times again after the fourth data DATA4 is stored in the eighth region REGION8, new program data including the fourth data DATA4 and the changed stream ID of 9 may be stored in the ninth region REGION9. The fourth data DATA4 stored in the eighth region REGION8 may be invalidated.

Subsequently, garbage collection may be performed ten times again on the fourth data DATA4 stored in the ninth region REGION9. When the garbage collection is performed on the fourth data DATA4 ten times again, new program data including the fourth data DATA4 and the changed stream ID of 10 may be stored in the tenth region REGION10. The fourth data DATA4 stored in the ninth region REGIONS may be invalidated.

Subsequently, garbage collection may be performed ten times again on the fourth data DATA4 stored in the tenth region REGION10. However, since the stream ID of the fourth data DATA4 is 10 and there is no stream ID to change, although garbage collection is performed on the fourth data DATA4, the stream ID of 10 the same as before may be assigned thereto. In other words, when the garbage collection is performed ten times on the fourth data DATA4 in the tenth region REGION10, no changes may be made to the data and the stream ID, the existing data stored in the tenth region REGION10 may be maintained.

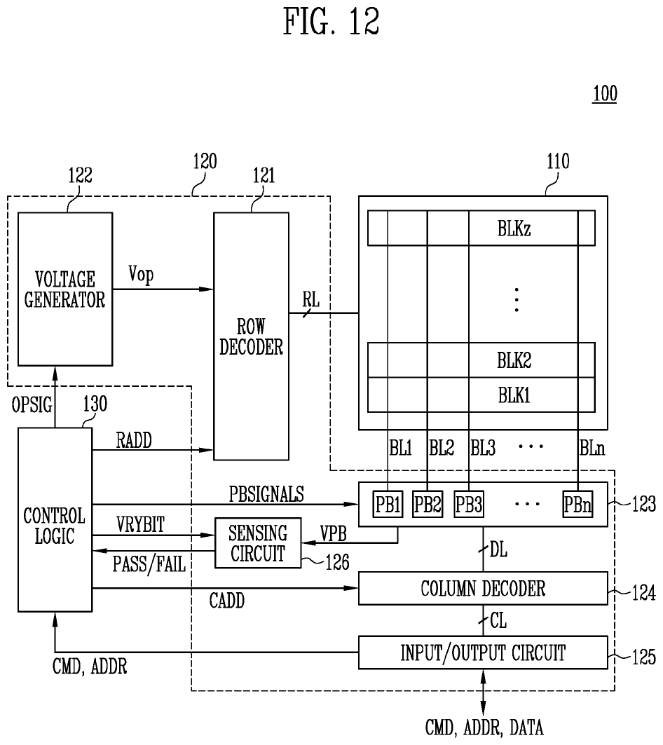

FIG. 12 is a diagram illustrating a structure of the memory device 100 shown in FIG. 1.

Referring to FIG. 12, the memory device 100 may include a memory cell array 110, a peripheral circuit 120, and control logic 130.

The memory cell array 110 may include a plurality of memory blocks BLK1 to BLKz, which may be coupled to a row decoder 121 through row lines RL. The memory blocks BLK1 to BLKz may be coupled to a page buffer group 123 through bit lines BL1 to BLn. Each of the plurality of memory blocks BLK1 to BLKz may include a plurality of memory cells. In an embodiment, the plurality of memory cells may be nonvolatile memory cells. Memory cells coupled to the same word line may be defined as one page. Therefore, each memory block may include a plurality of pages.

The row lines RL may include at least one source select line, a plurality of word lines and at least one drain select line.

Each of the memory cells may be a single level cell (SLC) storing one data bit, a multi-level cell (MLC) storing two data bits, a triple level cell (TLC) storing three data bits, or a quadruple level cell (QLC) storing four data bits.

The peripheral circuit 120 may be configured to perform program, read and erase operations on the selected area of the memory cell array 110 in response to control of the control logic 130. The peripheral circuit 120 may drive the memory cell array 110. For example, the peripheral circuit 120 may apply various operating voltages to the row lines RL and the bit lines BL1 to BLn or discharge the applied voltages in response to control of the control logic 130.

The peripheral circuit 120 may include the row decoder 121, the voltage generator 122, the page buffer group 123, a column decoder 124, an input/output circuit 125, and a sensing circuit 126.

The row decoder 121 may be coupled to the memory cell array 110 through the row lines RL. The row lines RL may include at least one source select line, a plurality of word lines and at least one drain select line. According to an embodiment, the word lines may include normal word lines and dummy word lines. According to an embodiment, the row lines RL may further include a pipe select line.

The row decoder 121 may be configured to decode the row address RADD received from the control logic 130. The row decoder 121 may select at least one memory block among the memory blocks BLK1 to BLKz according to the decoded block address. The row decoder 121 may select at least one word line of the selected memory block so as to apply voltages generated by the voltage generator 122 to at least one word line according to the decoded address.

For example, during a program operation, the row decoder 121 may apply a program voltage to the selected word line and a program pass voltage less than the program voltage to unselected word lines. During a program verify operation, the row decoder 121 may apply a verify voltage to the selected word line and a verify pass voltage greater than the verify voltage to the unselected word lines. During a read operation, the row decoder 121 may apply a read voltage to the selected word line and a read pass voltage greater than the read voltage to the unselected word lines.

According to an embodiment, an erase operation of the memory device 100 may be performed in units of memory blocks. During an erase operation, the row decoder 121 may select one of the memory blocks according to the decoded address. During the erase operation, the row decoder 121 may apply a ground voltage to word lines coupled to the selected memory block.

The voltage generator 122 may be controlled by the control logic 130. The voltage generator 122 may be configured to generate a plurality of voltages by using an external power voltage supplied to the memory device 100. More specifically, the voltage generator 122 may generate various operating voltages Vop for program, read and erase operations in response to an operation signal OPSIG. For example, the voltage generator 122 may generate a program voltage, a verify voltage, a pass voltage, a read voltage, and an erase voltage in response to the control of the control logic 130.

According to an embodiment, the voltage generator 122 may generate an internal power voltage by regulating an external power voltage. The internal power voltage generated by the voltage generator 122 may serve as an operating voltage of the memory device 100.

According to an embodiment, the voltage generator 122 may generate a plurality of voltages by using the external power voltage or the internal power voltage.

For example, the voltage generator 122 may include a plurality of pumping capacitors receiving the internal power voltage and generate a plurality of voltages by selectively activating the plurality of pumping capacitors in response to the control of the control logic 130.

The plurality of generated voltages may be supplied to the memory cell array 110 by the row decoder 121.

The page buffer group 123 may include first to nth page buffers PB1 to PBn, which may be coupled to the memory cell array 110 through the first to nth bit lines BL1 to BLn, respectively. The first to nth page buffers PB1 to PBn may operate in response to the control of the control logic 130. More specifically, the first to nth page buffers PB1 to PBn may operate in response to page buffer control signals PBSIGNALS. For example, the first to nth page buffers PB1 to PBn may temporarily store data received through the bit lines BL1 to BLn, or may sense voltages or currents in the bit lines BL1 to BLn during a read or verify operation.

More specifically, during a program operation, the first to nth page buffers PB1 to PBn may transfer the data DATA received through the input/output circuit 125 to selected memory cells through the first to nth bit lines BL1 to BLn when a program voltage is applied to a selected word line during a program operation. Memory cells of the selected page may be programmed according to the transferred data DATA. During a program verify operation, the first to nth page buffers PB1 to PBm may read page data by sensing the voltage or current received from the selected memory cells through the first to nth bit lines BL1 to BLn, respectively.

During a read operation, the first to nth page buffers PB1 to PBn may read the data DATA from the memory cells of the selected page through the first to nth bit lines BL1 to BLn and output the read data DATA to the input/output circuit 125 in response to control of the column decoder 124.

During an erase operation, the first to nth page buffers PB1 to PBn may float or apply an erase voltage to the first to nth bit lines BL1 to BLn.

The column decoder 124 may transfer data between the input/output circuit 125 and the page buffer group 123 in response to a column address CADD. For example, the column decoder 124 may exchange data with the first to nth page buffers PB1 to PBn through the data lines DL, or may exchange data with the input/output circuit 125 through column lines CL.

The input/output circuit 125 may transfer the command CMD and the address ADD from the memory controller 200 of FIG. 1 to the control logic 130, or may exchange the data DATA with the column decoder 124.

The sensing circuit 126 may generate a reference current in response to an allowable bit signal VRYBIT and compare a sensing voltage VPB received from the page buffer group 123 with a reference voltage generated by the reference current to output a pass signal PASS or a fail signal FAIL during a read operation or a verify operation.

The control logic 130 may control the peripheral circuit 120 by outputting the operation signal OPSIG, the row address RADD, the page buffer control signals PBSIGNALS and the allowable bit signal VRYBIT in response to the command CMD and the address ADD. For example, the control logic 130 may control a read operation of a selected memory block in response to a sub-block read command and an address. In addition, the control logic 130 may control an erase operation of a selected sub-block included in the selected memory block in response to a sub-block erase command and an address. In addition, the control logic 130 may determine whether a verify operation passes or fails in response to the pass or fail signal PASS or FAIL.

The memory cells included in the memory cell array 110 may be programmed into one of a plurality of program states according to data stored in each of the memory cells. A target program state of a memory cell may be determined as one of the plurality of program states according to data stored therein.

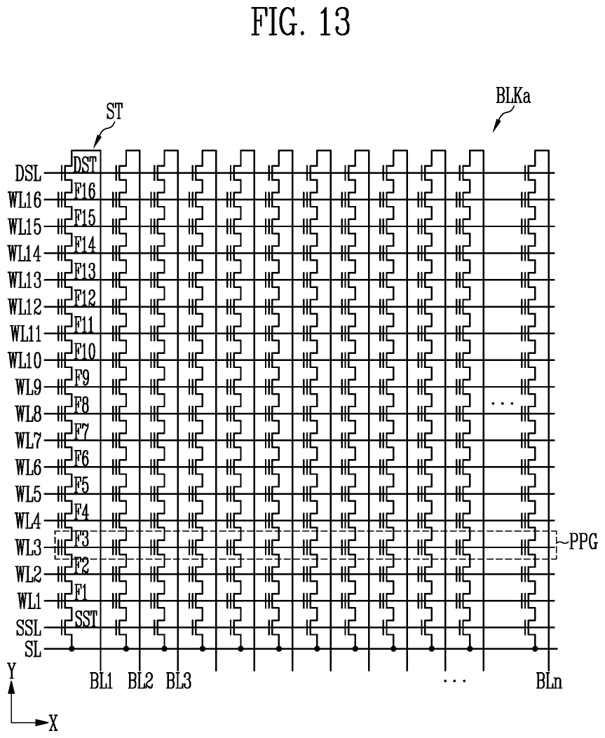

FIG. 13 is a diagram illustrating a memory block.

Referring to FIGS. 12 and 13, FIG. 13 is a circuit diagram illustrating one memory block BLKa among a plurality of the memory blocks BLK1 to BLKz included in the memory cell array 110 of FIG. 12.

A first select line, word lines and a second select line arranged in parallel with each other may be coupled to the memory block BLKa. For example, the word lines may be arranged in parallel between the first and second select lines. The first select line may be a source select line SSL and the second select line may be a drain select line DSL.

Specifically, the memory block BLKa may include a plurality of strings coupled between the bit lines BL1 to BL and a source line SL. The bit lines BL1 to BLn may be coupled to the strings, respectively, and the source line SL may be commonly coupled to the strings. Since each of the strings may have the same configuration, a string ST coupled to the first bit line BL1 is described in more detail below as an example.

The string ST may include a source select transistor SST, a plurality of memory cells F1 to F16, and a drain select transistor DST coupled in series between the source line SL and the first bit line BL1. Each string ST may include at least one source select transistor SST, at least one drain select transistors DST, and each string may include more than 16 memory cells F1 to F16 as shown in FIG. 13.

A source of the source select transistor SST may be coupled to the source line SL and a drain of the drain select transistor DST may be coupled to the first bit line BL1. The memory cells F1 to F16 may be coupled in series between the source select transistor SST and the drain select transistor DST. Gates of the source select transistors SST included in different strings ST may be coupled to the source select line SSL, gates of the drain select transistors DST may be coupled to the drain select line DSL, and gates of the memory cells F1 to F16 may be coupled to the plurality of word lines WL1 to WL16. A group of memory cells coupled to the same word line, among memory cells included in different strings ST, may be referred to as a physical page PPG. Therefore, the memory block BLKa may include as many physical pages PPG as the number of word lines WL1 to WL16.

One memory cell may store one-bit data. This memory cell is generally referred to as a single level cell (SLC). One physical page PPG may store one logical page (LPG) data. One LPG data may include as many data bits as the number of cells included in one physical page PPG. However, a single memory cell may store two or more bits of data. This memory cell is typically referred to as a multi-level cell (MLC). One physical page PPG including MLCs may store data corresponding to two or more logical pages LPG.

As the number of bits of data that may be stored in one memory cell has increased, the term multi-level cell (MLC) is used in a more specific sense to refer to a memory cell in which two bits of data are stored. A memory cell in which three or more bits of data are stored is referred to as a triple level cell (TLC). A memory cell in which four or more bits of data are stored is referred to as a quadruple level cell (QLC). In general, the present invention is applicable to a memory device having memory cells in which two or more bits of data are stored.

In another embodiment, a memory block may have a three-dimensional structure. Each memory block may include a plurality of memory cells stacked over a substrate. The plurality of memory cells may be arranged in +X direction, +Y direction and +Z direction.

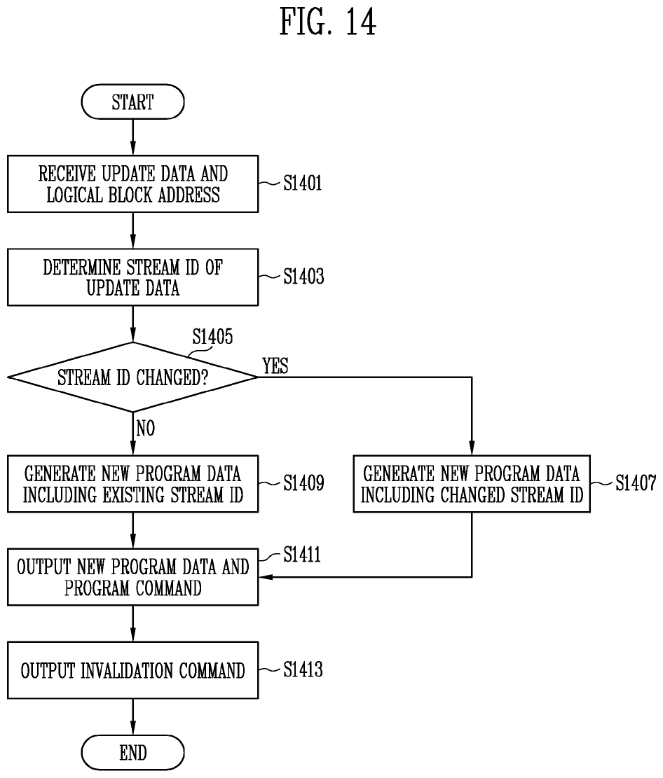

FIG. 14 is a diagram illustrating operations of a memory controller according to an embodiment of the present disclosure.

Referring to FIG. 14, at step S1401, a memory controller may receive update data and a logical block address from a host. The update data to be programmed into the memory device may be new data to change or replace previously stored data. The logical block address may indicate a position at which the previous data is stored.

At step S1403, the memory controller may determine a stream ID of the update data. More specifically, the memory controller may accumulate and count logical block addresses received together with the update data whenever the memory controller receives the update data. Further, the memory controller may accumulate and count the number of times that a garbage collection is performed on the data corresponding to the received logical block address.

Subsequently, when the update data is received, an update count obtained by counting the logical block address received together with the update data and a garbage collection count obtained by counting the number of times that data is moved to another memory block, are also received.

For example, when the update count is a first reference value or more, the memory controller may reduce the stream ID by 1. When the garbage collection count is a second reference value or more, the memory controller may increase the stream ID by 1.

At step S1405, the memory controller may determine whether or not the stream ID has changed. In other words, the memory controller may determine whether the stream ID has increased or decreased from the existing stream ID. As a result of determination, when the stream ID has changed (Y), the process flow may proceed to step S1407. In addition, when the stream ID has not changed (N), i.e., when the existing stream ID is maintained, the process flow may proceed to step S1409.

When the stream ID is changed, i.e., when the stream ID has increased or decreased from the existing stream ID, the memory controller may generate new program data including the changed stream ID (S1407).

However, when the stream ID has not changed, the memory controller may generate new program data including the existing stream ID (S1409).

According to an embodiment, when the new program data is generated at step S1407 or S1409, the memory controller may output the new program data and a program command for programming the new program data to the memory device (S1411). The memory device may program the new program data in response to the program command.

At step S1413, the memory controller may output an invalidation command. The invalidation command may be for invalidating data stored in the memory device prior to update. In other words, as the existing data stored in the memory device is updated, the existing data may be invalidated by invalidating the mapping relationship indicating the location of the existing data.

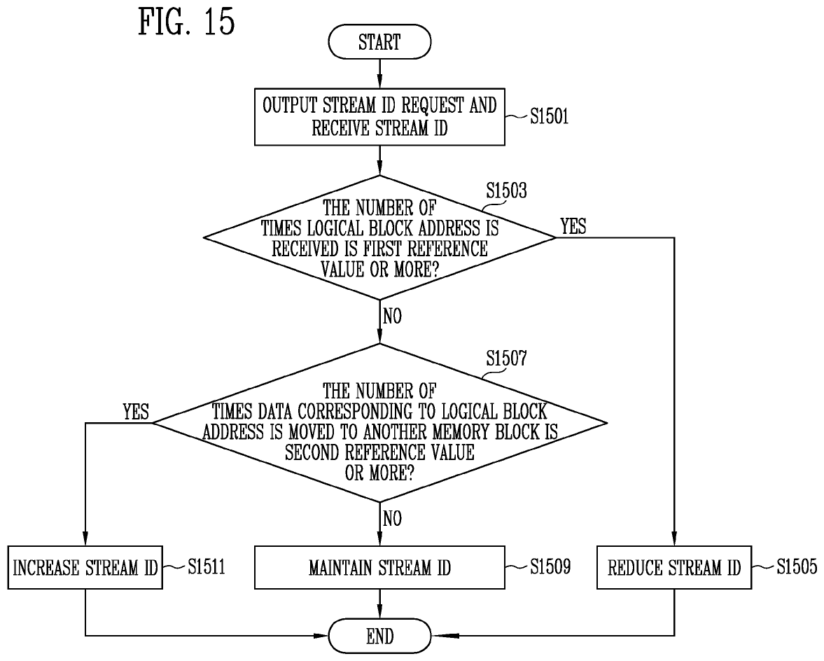

FIG. 15 is a diagram illustrating operations of the memory controller according to an embodiment of the present disclosure.

Referring to FIGS. 14 and 15, step S1403 is subdivided into steps S1501 and S1511. In other words, FIG. 15 shows processes for determining a stream ID of update data.

When the memory controller receives update data and a logical block address from the host, at step S1501, the memory controller may output a stream ID request for acquiring a stream ID of data stored in a physical block address having a mapping relationship with the received logical block address to the memory device, and may receive the stream ID from the memory device.

Subsequently, at step S1503, the memory controller may determine whether the number of times that the logical block address is received is a first reference value or more. In other words, the memory controller may determine whether an update count, obtained by counting logical block addresses received with the update data, is the first reference value or more. The update count may indicate the number of times that the data corresponding to the received logical block address is updated.

When the number of times that the logical block address is received is the first reference value or more (Y), the memory controller may reduce the stream ID. However, when the number of times that the logical block address is received is not the first reference value or more (N), the process flow may proceed to step S1507.

At step S1507, the memory controller may determine whether the data corresponding to the logical block address is moved to another memory block is a second reference value or more. In other words, the memory controller may determine the number of times that the data corresponding to the logical block address is moved to another memory block by the garbage collection GC.

When the number of times that the data corresponding to the logical block address is moved to another memory block is the second reference value or more (Y), the memory controller may increase the stream ID (S1511). However, when the number of times that the data corresponding to the logical block address is moved to another memory block is not the second reference value or more (N), the memory controller may maintain the stream ID (S1511). In other words, the existing stream ID may be maintained.

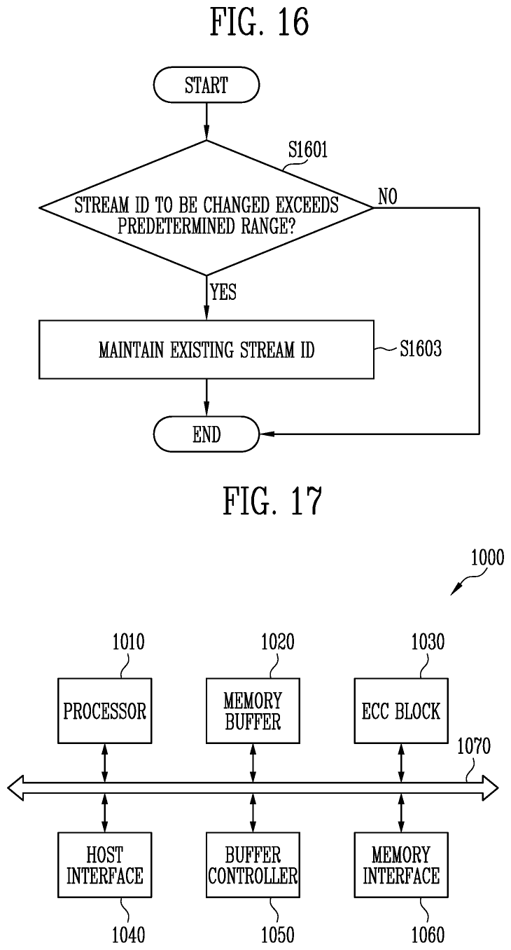

FIG. 16 is a diagram illustrating operations of the memory controller according to an embodiment.

Referring to FIG. 16, at step S1601, the memory controller may determine whether a stream ID to be changed exceeds a predetermined range.

More specifically, assume that the range of possible stream IDs is between 1 to 10. Then, there may be a situation in which the number of times that a logical block address corresponding to data having a stream ID of 1 may be a first reference value or more. However, since there is no stream ID of less than 1, reducing the stream ID would exceed the predetermined range.

The same is true on the other end of the range. That is, the number of times that data having a stream ID of 10 is moved to another memory block may be a second reference value or more. However, since there is no stream ID of more than 10, increasing the stream ID would exceed the predetermined range.

Thus, when changing the stream ID would exceed the predetermined range (Y), the memory controller may maintain the existing stream ID (S1603). In other words, in this circumstance, the stream ID may not be changed.

FIG. 17 is a diagram illustrating another embodiment of the memory controller 200 of FIG. 1.

A memory controller 1000 of FIG. 17 may be coupled to a host and a memory device. In response to a request from the host, the memory controller 1000 may access the memory device. For example, the memory controller 1000 may control write, read, erase, and background operations of the memory device. The memory controller 1000 may provide an interface between the memory device and the host. The memory controller 1000 may drive firmware for controlling the memory device.

Referring to FIG. 17, the memory controller 1000 may include a processor 1010, a memory buffer 1020, an error correction code (ECC) block 1030, a host interface 1040, a buffer control circuit 1050, a memory interface 1060, and a bus 1070.

The bus 1070 may provide a channel between components of the memory controller 1000.

The processor 1010 may control overall operation of the memory controller 1000 and may perform a logical operation. The processor 1010 may communicate with an external host through the host interface 1040 and communicate with the memory device through the memory interface 1060. Further, the processor 1010 may communicate with the memory buffer 1020 through the buffer control circuit 1050. The processor 1010 may control operations of the storage device by using the memory buffer 1020 as a working memory, a cache memory or a buffer memory.

The processor 1010 may perform the function of a flash translation layer (FTL). The processor 1010 may translate a logical block address LBA, provided by the host, into a physical block address PBA through the flash translation layer FTL. The flash translation layer FTL may receive the logical block address LBA and translate the logical block address LBA into the physical block address PBA by using a mapping table. There are various address mapping methods for the flash translation layer FTL, depending on a mapping unit. Typical address mapping methods include a page mapping method, a block mapping method and a hybrid mapping method.

According to an embodiment, the processor 1010 may receive host data from the host 300 of FIG. 1. The host data may include an initial stream ID. The initial stream ID may be given 4 (HOT) or 7 (COLD) on the basis of a data extension, or a file format of the data.

After the host data is programmed into the memory device 100 of FIG. 1, the processor 1010 may receive the update data from the host 300 of FIG. 1. The update data may be new data for changing the data programmed into the memory device 100 of FIG. 1.

The processor 1010 may determine a stream ID of the update data on the basis of the update count and a garbage collection count. The update count may have a value by counting the number of times that a logical block address is received together with the update data. The garbage collection count may have a value by counting the number of times that the data is moved to another memory block by garbage collection without changing the data.

According to an embodiment, the processor 1010 may receive the existing stream ID from the memory device 100 of FIG. 1, and may maintain or change the existing stream ID. For example, when the update count is the first reference value or more, or the garbage collection count is the second reference value or more, the processor 1010 may increase or decrease the existing stream ID.

The processor 1010 may randomize data received from the host. For example, the processor 1010 may use a randomizing seed to randomize data received from the host. The randomized data may be provided, as data to be stored, to the memory device and may be programmed in the memory cell array.

The processor 1010 may run software or firmware to perform randomizing and derandomizing operations.

The memory buffer 1020 may serve as an operation memory, a cache memory, or a buffer memory of the processor 1010. The memory buffer 1020 may store codes and commands executed by the processor 1010. The memory buffer 1020 may store data that is processed by the processor 1010. The memory buffer 1020 may include a static RAM (SRAM) or a dynamic RAM (DRAM).

The ECC block 1030 may perform error correction. The ECC block 1030 may perform ECC encoding based on data to be written to the memory device through the memory interface 1060. The ECC-encoded data may be transferred to the memory device through the memory interface 1060. The ECC block 1030 may perform ECC decoding based on data received from the memory device through the memory interface 1060. For example, the ECC block 1030 may be included as the component of the memory interface 1060 in the memory interface 1060.

The host interface 1040 may communicate with the external host under the control of the processor 1010. The host interface 1040 may communicate with the external host using at least one of various communication methods such as Universal Serial Bus (USB), Serial AT Attachment (SATA), Serial Attached SCSI (SAS), High Speed Interchip (HSIC), Small Computer System Interface (SCSI), Peripheral Component Interconnection (PCI), PCI express (PCIe), Nonvolatile Memory express (NVMe), Universal Flash Storage (UFS), Secure Digital (SD), MultiMedia Card (MMC), embedded MMC (eMMC), Dual In-line Memory Module (DIMM), Registered DIMM (RDIMM), and/or Load Reduced DIMM (LRDIMM) communication methods.

The buffer control circuit 1050 may control the memory buffer 1020 under the control of the processor 1010.

The memory interface 1060 may communicate with the memory device under the control of the processor 1010. The memory interface 1060 may transmit/receive commands, addresses, and data to/from the memory device through channels.

For example, the memory controller 1000 may not include the memory buffer 1020 and the buffer control circuit 1050. One or both of these components may be provided separately.

For example, the processor 1010 may control the operations of the memory controller 1000 using codes. The processor 1010 may load codes from a nonvolatile memory device (e.g., ROM) provided in the memory controller 1000. In another example, the processor 1010 may load codes from the memory device through the memory interface 1060.

For example, the bus 1070 of the memory controller 1000 may be divided into a control bus and a data bus. The data bus may be configured to transmit data in the memory controller 1000, and the control bus may be configured to transmit control information such as commands or addresses in the memory controller 1000. The data bus and the control bus may be isolated from each other so that neither interfere with, nor influence, the other. The data bus may be coupled to the host interface 1040, the buffer control circuit 1050, the ECC block 1030, and the memory interface 1060. The control bus may be coupled to the host interface 1040, the processor 1010, the buffer control circuit 1050, the memory buffer 1020, and the memory interface 1060.

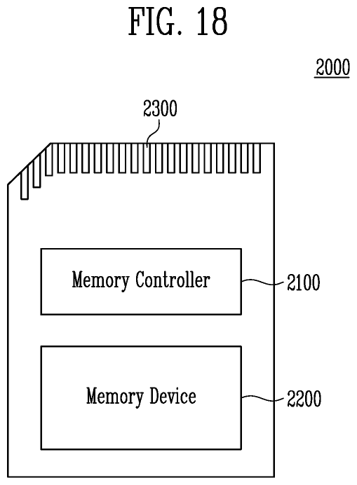

FIG. 18 is a block diagram illustrating a memory card system 2000 to which a storage device is applied according to an embodiment.

Referring to FIG. 18, the memory card system 2000 may include a memory controller 2100, a memory device 2200 and a connector 2300.

The memory controller 2100 may be coupled to the memory device 2200. The memory controller 2100 may access the memory device 2200. For example, the memory controller 2100 may control read, write, erase, and background operations of the memory device 2200. The memory controller 2100 may be configured to provide an interface between the memory device 2200 and the host. The memory controller 2100 may be configured to drive firmware for controlling the memory device 2200. The memory device 2200 may be configured the same as the memory device 100 described above with reference to FIG. 1.

In an embodiment, the memory controller 2100 may include components, such as a Random Access Memory (RAM), a processor, a host interface, a memory interface, and an ECC block.

The memory controller 2100 may communicate with an external device through the connector 2300. The memory controller 2100 may communicate with an external device (e.g., host) based on a specific communication protocol. For example, the memory controller 2100 may communicate with the external device through at least one of various communication protocols such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer small interface (SCSI), enhanced small disk interface (ESDI), integrated drive electronics (IDE), Firewire, universal flash storage (UFS), WiFi, Bluetooth, and/or nonvolatile memory express (NVMe) protocols. For example, the connector 2300 may be defined by at least one of the above-described various communication protocols.

In an embodiment, the memory device 2200 may be embodied as any of various nonvolatile memory devices, such as an Electrically Erasable and Programmable ROM (EEPROM), a NAND flash memory, a NOR flash memory, a Phase-change RAM (PRAM), a Resistive RAM (ReRAM), a Ferroelectric RAM (FRAM), and/or a Spin-Torque Magnetic RAM (STT-MRAM).

According to an embodiment, the memory controller 2100 may receive host data from the host 300 of FIG. 1. The host data may include an initial stream ID. The initial stream ID may be given 4 (HOT) or 7 (COLD) on the basis of a data extension, or a file format of the data.

After the host data is programmed into the memory device 2200, the memory controller 2100 may receive the update data from the host 300 of FIG. 1. The update data may be new data for changing the data programmed into the memory device 2200.

The memory controller 2100 may determine a stream ID of the update data on the basis of the update count and a garbage collection count. The update count may have a value by counting the number of times that a logical block address is received together with the update data. The garbage collection count may have a value by counting the number of times that the data is moved to another memory block by garbage collection without changing the data.

According to an embodiment, the memory controller 2100 may receive the existing stream ID from the memory device 2200 of FIG. 1, and may maintain or change the existing stream ID. For example, when the update count is the first reference value or more, or the garbage collection count is the second reference value or more, the memory controller 2100 may increase or decrease the existing stream ID.

The memory controller 2100 and the memory device 2200 may be integrated into a single semiconductor device to form a memory card, such as a personal computer memory card international association (PCMCIA), a compact flash card (CF), a smart media card (SM or SMC), a memory stick multimedia card (MMC, RS-MMC, or MMCmicro), an SD card (SD, miniSD, microSD, or SDHC), and/or a universal flash storage (UFS).

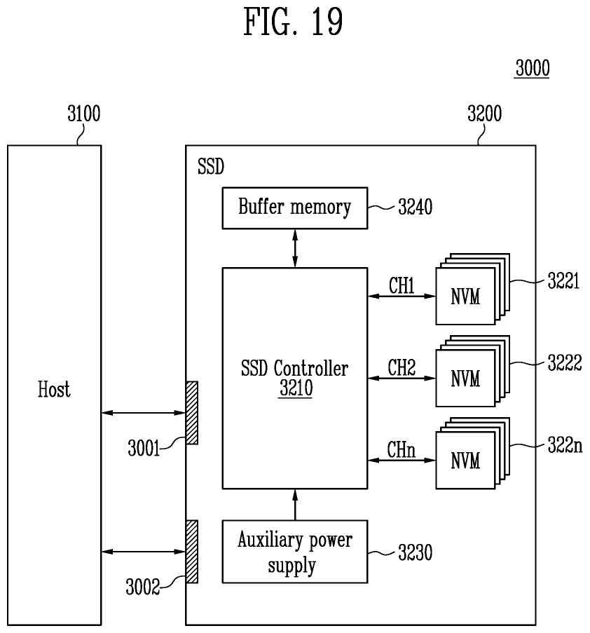

FIG. 19 is a block diagram illustrating an example of a solid state drive (SSD) system to which a storage device is applied according to an embodiment of the present disclosure.

Referring FIG. 19, the SSD system 3000 may include a host 3100 and an SSD 3200. The SSD 3200 may exchange signals SIG with the host 3100 through a signal connector 3001 and may receive power PWR through a power connector 3002. The SSD 3200 may include an SSD controller 3210, a plurality of flash memories 3221 to 322n, an auxiliary power supply 3230, and a buffer memory 3240.

In an embodiment, the SSD controller 3210 may perform the function of the memory controller 200, described above with reference to FIG. 1.

The SSD controller 3210 may control the plurality of flash memories 3221 to 322n in response to the signals SIG received from the host 3100. According to an embodiment, the signals SIG may be defined based on the interfaces of the host 3100 and the SSD 3200. According to an embodiment, the signals SIG may be based on the interfaces of the host 3100 and the SSD 3200. For example, the signals SIG may be defined by at least one of various interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer small interface (SCSI), enhanced small disk interface (ESDI), integrated drive electronics (IDE), Firewire, universal flash storage (UFS), WiFi, Bluetooth, and/or nonvolatile memory express (NVMe) interfaces.

According to an embodiment, the SSD controller 3210 may receive host data from the host 300 of FIG. 1. The host data may include an initial stream ID. The initial stream ID may be given 4 (HOT) or 7 (COLD) on the basis of a data extension, or a file format of the data.

After the host data is programmed into the memory device 3221, the SSD controller 3210 may receive the update data from the host 300 of FIG. 1. The update data may be new data for changing the data programmed into the memory device 2220.

The SSD controller 3210 may determine a stream ID of the update data on the basis of the update count and a garbage collection count. The update count may be obtained by counting the number of times that a logical block address is received together with the update data. The garbage collection count may be obtained by counting the number of times that the data is moved to another memory block by garbage collection without changing the data.

According to an embodiment, the SSD controller 3210 may receive the existing stream ID from the plurality of flash memories 3221 to 322n, and may maintain or change the existing stream ID. For example, when the update count is the first reference value or more, or the garbage collection count is the second reference value or more, the SSD controller 3210 may increase or decrease the existing stream ID.

The auxiliary power supply 3230 may be coupled to the host 3100 through the power connector 3002. The auxiliary power supply 3230 may be supplied and charged with the power PWR from the host 3100. The auxiliary power supply 3230 may supply the power of the SSD 3200 when power is not smoothly supplied from the host 3100. For example, the auxiliary power supply 3230 may be within or externally to the SSD 3200. For example, the auxiliary power supply 3230 may be disposed in a main board and may supply auxiliary power to the SSD 3200.

The buffer memory 3240 may function as a buffer memory of the SSD 3200. For example, the buffer memory 3240 may temporarily store data received from the host 3100 or data received from the plurality of flash memories 3221 to 322n, or may temporarily store metadata (e. g., mapping tables) of the flash memories 3221 to 322n. The buffer memory 3240 may include any of various volatile memories such as DRAM, SDRAM, DDR SDRAM, LPDDR SDRAM, and GRAM or nonvolatile memories such as FRAM, ReRAM, STT-MRAM, and PRAM.

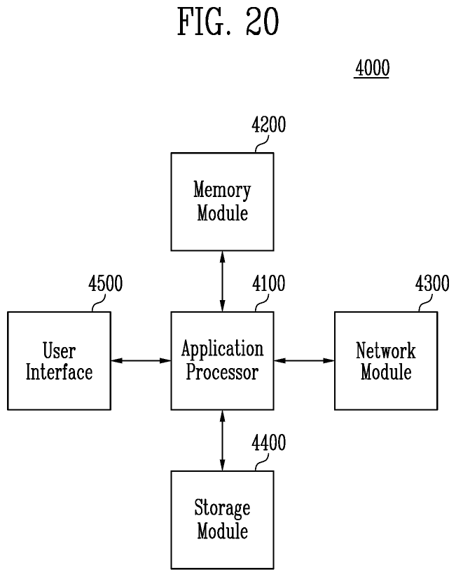

FIG. 20 is a block diagram illustrating a user system 4000 to which the storage device 50 is applied according to an embodiment.

Referring to FIG. 20, the user system 4000 may include an application processor 4100, a memory module 4200, a network module 4300, a storage module 4400, and a user interface 4500.

The application processor 4100 may run components included in the user system 4000, an operating system (OS), or a user program. For example, the application processor 4100 may include controllers, interfaces, graphic engines, etc. for controlling the components included in the user system 4000. The application processor 4100 may be provided as a system-on-chip (SoC).

According to an embodiment, the application processor 4100 may receive host data from the host 300 of FIG. 1. The host data may include an initial stream ID. The initial stream ID may be given 4 (HOT) or 7 (COLD) on the basis of a data extension, or a file format of the data.

After the host data is programmed into the storage module 4400, the application processor 4100 may receive the update data from the host 300 of FIG. 1. The update data may be new data for changing the data programmed into the storage module 4400.

The application processor 4100 may determine a stream ID of the update data on the basis of the update count and a garbage collection count. The update count may have a value by counting the number of times that a logical block address is received together with the update data. The garbage collection count may have a value by counting the number of times that the data is moved to another memory block by garbage collection without changing the data.

According to an embodiment, the application processor 4100 may receive the existing stream ID from the storage module 4400, and may maintain or change the existing stream ID. For example, when the update count is the first reference value or more, or the garbage collection count is the second reference value or more, the application processor 4100 may increase or decrease the existing stream ID.

The memory module 4200 may function as a main memory, a working memory, a buffer memory, or a cache memory of the user system 4000. The memory module 4200 may include volatile RAMs such as DRAM, SDRAM, DDR SDRAM, DDR2 SDRAM, DDR3 SDRAM, LPDDR SDARM, LPDDR3 SDRAM, and LPDDR3 SDRAM or nonvolatile RAMs such as PRAM, ReRAM, MRAM, and FRAM. For example, the application processor 4100 and the memory module 4200 may be packaged based on package-on-package (POP) and may then be provided as a single semiconductor package.

The network module 4300 may communicate with external devices. For example, the network module 4300 may support wireless communication, such as Code Division Multiple Access (CDMA), Global System for Mobile communication (GSM), wideband CDMA (WCDMA), CDMA-2000, Time Division Multiple Access (TDMA), Long Term Evolution (LTE), Wimax, WLAN, UWB, Bluetooth, or WiFi communication. For example, the network module 4300 may be included in the application processor 4100.

The storage module 4400 may store data. For example, the storage module 4400 may store data received from the application processor 4100. Alternatively, the storage module 4400 may transmit the data stored in the storage module 4400 to the application processor 4100. For example, the storage module 4400 may be embodied as a nonvolatile semiconductor memory device, such as a Phase-change RAM (PRAM), a Magnetic RAM (MRAM), a Resistive RAM (RRAM), a NAND flash memory, a NOR flash memory, or a NAND flash memory having a three-dimensional (3D) structure. For example, the storage module 4400 may be provided as a removable storage medium (i.e., removable drive), such as a memory card or an external drive of the user system 4000.

For example, the storage module 4400 may include a plurality of nonvolatile memory devices, which may be operated in the same manner as the memory device described above with reference to FIGS. 11 and 12. The storage module 4400 may operate in the same manner as the storage device 50 described above with reference to FIG. 1.

The user interface 4500 may include interfaces which input data or instructions to the application processor 4100 or output data to an external device. According to an embodiment, the user interface 4500 may include user input interfaces such as a keyboard, a keypad, a button, a touch panel, a touch screen, a touch pad, a touch ball, a camera, a microphone, a gyroscope sensor, a vibration sensor, and/or a piezoelectric device. The user interface 4500 may further include user output interfaces such as a Liquid Crystal Display (LCD), an Organic Light Emitting Diode (OLED) display device, an Active Matrix OLED (AMOLED) display device, an LED, a speaker, and a monitor.

According to embodiments of the present disclosure, a variable stream ID of data, instead of a fixed stream ID, may be used according to the number of updates of data and the number of times garbage collection is performed, so that reliability of the stream ID of the data may be increased.

In the above-discussed embodiments, one or more steps may be selectively performed or skipped. In some cases, the steps need not be performed in the stated order. Furthermore, the disclosed embodiments are intended to help those with ordinary knowledge in this art more clearly understand the present invention, not to limit the bounds of the present invention. In other words, one of ordinary skill in the art to which the present disclosure belongs will be able to easily understand that various modifications are possible based on the technical scope of the present disclosure. It will be apparent to those skilled in the art that various modifications can be made to the disclosed embodiments without departing from the spirit or scope of the invention. Thus, it is intended that the present invention cover all such modifications provided they come within the scope of the appended claims and their equivalents.

What is claimed is:

1. A memory controller controlling a memory device, the memory controller comprising:
a flash transition layer generating a mapping relationship of first data received from a host on the basis of a first stream ID included in the first data;
a stream ID controller receiving second data for updating the first data stored in the memory device on the basis of the mapping relationship generated based on the first stream ID, and determining a second stream ID to be assigned to the second data; and
a request controller outputting a program command for storing the first data in the memory device and a program command for storing third data including the second data and the second stream ID in the memory device,
wherein the request controller determines the program command for storing the third data in the memory device on the basis of the mapping relationship generated by the flash transition layer on the basis of the second stream ID.

2. The memory controller of claim 1,
wherein the flash transition layer maps a logical block address received together with the first data to a physical block address indicating a region where hot data is stored when the first stream ID indicates the hot data, and
wherein the flash translation layer maps the logical block address received together with the first data to a physical block address indicating a region where cold data is stored when the first stream ID indicates the cold data.

3. The memory controller of claim 1, wherein, when the stream ID controller receives the second data, the stream ID controller outputs a stream ID request for obtaining the first stream ID to the memory device, and receives the first stream ID corresponding to the stream ID request from the memory device.

4. The memory controller of claim 3, wherein the third data includes the second data and the second stream ID maintaining or changing a value corresponding to the first stream ID.

5. The memory controller of claim 3, wherein the stream ID controller generates an update count by counting a number of times that a logical block address for updating the second data is received together with the second data and a garbage collection count by counting a number of times that data stored in a physical block address corresponding to the logical block address received together with the second data is moved to another memory block in the memory device.

6. The memory controller of claim 5, wherein the stream ID controller reduces a value of the first stream ID when the update count is a first reference value or more.

7. The memory controller of claim 6, wherein the stream ID controller maintains the value of the first stream ID when the value of the first stream ID is a minimum value among a set range of values and the update count is the first reference value or more.

8. The memory controller of claim 5, wherein the stream ID controller increases a value of the first stream ID when the garbage collection count is a second reference value or more.

9. The memory controller of claim 8, wherein the stream ID controller maintains the value of the first stream ID when the value of the first stream ID is a maximum value among a set range of values and the garbage collection count is the second reference value or more.

10. The memory controller of claim 1, wherein the stream ID controller comprises:
an update counter generating an update count by counting a number of times that a logical block address of updating second data is received together with the second data;
a garbage collection counter generating a garbage collection count by counting a number of times that data stored in a physical block address corresponding to the logical block address received together with the second data is moved to another memory block in the memory device;
a stream ID changer determining the second stream ID to be assigned to the second data; and
a data generator generating the third data including the second data and the second stream ID.

11. The memory controller of claim 10, wherein, when the stream ID controller receives the second data, the stream ID changer outputs a stream ID request for obtaining the first stream ID from the memory device, and receives the first stream ID corresponding to the stream ID request from the memory device.

12. The memory controller of claim 11, wherein the stream ID changer reduces a value of the first stream ID when the update count is a first reference value or more, and increases the value of the first stream ID when the garbage collection count is a second reference value or more.

13. The memory controller of claim 11, wherein the stream ID changer maintains a value corresponding to the first stream ID when a value obtained by reducing or increasing the value corresponding to the first stream ID exceeds predetermined values.

14. A method of operating a memory controller controlling a memory device, the method comprising:
receiving first data from a host;
generating a mapping relationship of the first data on the basis of a first stream ID included in the first data;
outputting a program command for storing the first data in the memory device on the basis of the mapping relationship;
receiving second data for updating the first data from the host; and
determining a second stream ID to be assigned to the second data.

15. The method of claim 14, wherein the determining of the second stream ID to be assigned to the second data comprises:
outputting a stream ID request for obtaining the first stream ID to the memory device; and
receiving the first stream ID corresponding to the stream ID request from the memory device.

16. The method of claim 15, further comprising generating third data including the second data and the second stream ID maintaining or changing a value corresponding to the first stream ID.

17. The method of claim 14, further comprising generating an update count by counting a number of times that a logical block address for updating the second data is received together with the second data and a garbage collection count by counting a number of times that data stored in a physical block address corresponding to the logical block address received together with the second data is moved to another memory block in the memory device.

18. The method of claim 17, wherein the determining of the second stream ID to be assigned to the second data comprises reducing a value of the first stream ID when the update count is a first reference value or more.

19. The method of claim 17, wherein the determining of the second stream ID to be assigned to the second data comprises increasing a value of the first stream ID when the garbage collection count is a second reference value or more.

20. The method of claim 17, wherein the determining of the second stream ID to be assigned to the second data comprises maintaining a value corresponding to the first stream ID when a value obtained by reducing or increasing the value corresponding to the first stream ID exceeds predetermined values.

21. A memory system comprising:
a memory device suitable for storing current data together with a current stream identification (ID) into a storage region corresponding to the current stream ID; and
a controller suitable for:
counting a number of times that a logical address is provided for updating the current data with updated data to generate a first number;
counting a number of times that a garbage collection operation is performed on a storage area corresponding to the logical address to generate a second number;
adjusting, in response to a request of updating the current data, a value of the current steam ID resulting in an adjusted stream ID based on the first and second numbers;
controlling the memory device to store the updated data together with the adjusted stream ID in a storage region corresponding to the adjusted stream ID; and
invalidating the current data together with the current stream ID.
